(19) United States
(12) Patent Application Publication
(10) Pub. No.: US 2017/0194300 A1
(43) Pub. Date: Jul. 6, 2017

(54) THERMALLY ENHANCED SEMICONDUCTOR ASSEMBLY WITH THREE DIMENSIONAL INTEGRATION AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/462,536

(22) Filed: Mar. 17, 2017

Related U.S. Application Data
(63) Continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/289,126 is a continuation-in-part of application No. 15/166,185, filed on May 26, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
(60) Provisional application No. 62/166,771, filed on May 27, 2015.

(51) Int. Cl. H01L 25/10; H01L 25/00

(52) U.S. Cl. CPC H01L 25/105; H01L 25/50; H01L 2225/1041; H01L 2225/1058; H01L 2225/1094; H01L 2225/1082

(57) ABSTRACT

A thermally enhanced semiconductor assembly with three dimensional integration includes a first component and a second component face-to-face mounted together. A heat spreader that provides an enhanced thermal characteristic for the semiconductor assembly is disposed in a through opening of a routing circuitry. Another routing circuitry disposed on the heat spreader not only provides mechanical support, but also allows heat spreading and electrical grounding for the heat spreader by metallized vias.

### CROSS REFERENCE TO RELATED APPLICATIONS

This application is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The entirety of each of said Applications is incorporated herein by reference.

### FIELD OF THE INVENTION

The present invention relates to a semiconductor assembly and, more particularly, to a thermally enhanced face-to-face semiconductor assembly in which a heat spreader is integrated in the assembly through dual routing circuitries, and a method of making the same.

### DESCRIPTION OF RELATED ART

Market trends of multimedia devices demand for faster and slimmer designs. One of assembly approaches is to interconnect two semiconductor components with “face-to-face” configuration so that the routing distance between the two components can be the shortest possible. As the stacked semiconductor components can talk directly to each other with reduced latency, the assembly's signal integrity and additional power saving capability are greatly improved. However, as semiconductor components are susceptible to performance degradation at high operational temperatures, stacking devices with face-to-face configuration without proper heat dissipation would worsen devices' thermal environment and may cause immediate failure during operation. Despite numerous attempts to improve thermal performance of semiconductor assemblies by inserting a heat sink in a wiring board have been reported in the literature, many mechanical-related deficiencies remain. For example, wiring boards and their assemblies disclosed by U.S. Pat. Nos. 5,583,377, 6,861,750, 7,202,559, 7,462,933, 7,554,194, 7,919,853, 7,944,043, 8,188,379, 8,519,537, and 8,686,558 may render reliability and mechanical degradation problems. This is largely due to the heat sink disposed in the through opening is barely supported by the wiring board through flanges or adhesives, thermal expansion and shrinkage of the wiring board during operation would cause heat sink dislocation or distortion.

Further, as the heat sink in the wiring board is often electrically and thermally isolated and its planar dimension is confined by the size of the through opening, the electrical and thermal performances of the assemblies are significantly limited.

Additionally, U.S. Pat. Nos. 8,008,121, 8,519,537 and 8,558,395 disclose various assembly structures having an interposer disposed in between the face-to-face chips. Although there is no TSV in the stacked chips, the TSV in the interposer that serves for circuitry routing between chips induces complicated manufacturing processes, high yield loss and excessive cost.

For the reasons stated above, and for other reasons stated below, an urgent need exists to provide a new semiconductor assembly that can address high packaging density, better signal integrity, high thermal dissipation and robust mechanical reliability requirements.

### SUMMARY OF THE INVENTION

The objective of the present invention is to provide a semiconductor assembly with semiconductor components face-to-face assembled together through a buildup circuitry, and has a heat spreader to provide electromagnetic shielding and heat dissipation for the device directly attached thereon. The heat spreader is disposed in a through opening of a routing circuitry and mechanically supported by, electrically connected with, and thermally dissipated through another routing circuitry, thereby improving mechanical, thermal and electrical performances of the assembly.

In accordance with the foregoing and other objectives, the present invention provides a semiconductor assembly having a first component electrically coupled to a second component. The first component includes a first device and a buildup circuitry, whereas the second component includes a second device, a first routing circuitry, a second routing circuitry and a heat spreader. In a preferred embodiment, the first device is electrically coupled to one surface of the buildup circuitry and optionally sealed in a molding compound; the second device is electrically coupled to the other surface of the buildup circuitry by first bumps, and is disposed in a through opening of the first routing circuitry and thermally conductible to the heat spreader that is located in the through opening of the first routing circuitry and electrically coupled to the second routing circuitry for ground connection; the buildup circuitry provides primary fan-out routing and the shortest interconnection distance between the first device and the second device; the first routing circuitry laterally surrounds the second device and the heat spreader, and is electrically coupled to the buildup circuitry by second bumps to provide further fan-out routing; and the second routing circuitry covers the first routing circuitry and the heat spreader to provide mechanically support, and is thermally conductible to the heat spreader and electrically coupled to the first routing circuitry.

Accordingly, the present invention provides a thermally enhanced semiconductor assembly with three dimensional integration, comprising: a first component that includes a first device and a buildup circuitry, wherein the first device is electrically coupled to a first surface of the buildup circuitry; a second component that includes a second device, a first routing circuitry, a second routing circuitry and a heat spreader, wherein (i) the first routing circuitry has a first surface, an opposite second surface, and a through opening extending from the first surface to the second surface, (ii) the heat spreader is disposed in the through opening and has a backside surface substantially coplanar with the second surface of the first routing circuitry, (iii) the second routing circuitry is disposed on the backside surface of the heat spreader and the second surface of the first routing circuitry and electrically connected to the first routing circuitry and thermally conductible to the heat spreader through metallized vias, and (iv) the second device is attached to the heat spreader with a thermally conductive material and laterally surrounded by the first routing circuitry; and the first component is stacked over the second component, with the second device electrically coupled to a second surface of the buildup circuitry opposite to the first surface by an array of first bumps, and with the second surface of the buildup circuitry electrically coupled to the first surface of the first routing circuitry by an array of second bumps.

Additionally, the present invention provides a method of making a thermally enhanced semiconductor assembly with three dimensional integration, comprising: providing a first component that includes a first device and a buildup circuitry, wherein the first device is electrically coupled to a first surface of the buildup circuitry; providing a wiring board that includes a first routing circuitry, a second routing circuitry and a heat spreader, wherein (i) the first routing circuitry has a first surface, an opposite second surface, and a through opening extending from the first surface to the second surface, (ii) the heat spreader is disposed in the through opening and has a backside surface substantially coplanar with the second surface of the first routing circuitry, and (iii) the second routing circuitry is disposed on the backside surface of the heat spreader and the second surface of the first routing circuitry and electrically connected to the first routing circuitry and thermally conductible to the heat spreader through metallized vias; electrically coupling a second device to a second surface of the buildup circuitry of the first component opposite to the first surface through an array of first bumps; and stacking the first component over the wiring board and electrically coupling the first surface of the first routing circuitry to the second surface of the buildup circuitry of the first component by an array of second bumps, with the second device attached to the heat spreader and laterally surrounded by the first routing circuitry.

Unless specifically indicated or using the term “then” between steps, or steps necessarily occurring in a certain order, the sequence of the above-mentioned steps is not limited to that set forth above and may be changed or reordered according to desired design.

The semiconductor assembly and the method of making the same according to the present invention have numerous advantages. For instance, face-to-face electrically coupling the first component and the second component can offer the shortest interconnect distance between the first and second components. Inserting the second device into the through opening of the first routing circuitry of the wiring board is particularly advantageous as the wiring board can provide mechanical housing for the second device, whereas the heat spreader in the through opening and mechanically supported by the second routing circuitry can provide thermal dissipation for the second device. Additionally, electrically coupling the first routing circuitry to the buildup circuitry is beneficial as the buildup circuitry can provide primary fan-out routing whereas the first routing circuitry provides further fan-out routing.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of the structure with routing traces formed on a sacrificial carrier in accordance with the first embodiment of the present invention;

FIG. 2 is a cross-sectional view of the structure of FIG. 1 further provided with a dielectric layer and via openings in accordance with the first embodiment of the present invention;

FIG. 3 is a cross-sectional view of the structure of FIG. 2 further provided with conductive traces in accordance with the first embodiment of the present invention;

FIG. 4 is a cross-sectional view of the structure of FIG. 3 further provided with a first device in accordance with the first embodiment of the present invention;

FIG. 5 is a cross-sectional view of the structure of FIG. 4 further provided with metal posts in accordance with the first embodiment of the present invention;

FIG. 6 is a cross-sectional view of the structure of FIG. 5 further provided with a molding compound in accordance with the first embodiment of the present invention;

FIGS. 7 and 8 are cross-sectional and bottom perspective views, respectively, of the structure of FIG. 6 after removal of the sacrificial carrier in accordance with the first embodiment of the present invention;

FIGS. 9 and 10 are cross-sectional and bottom perspective views, respectively, of the structure of FIGS. 7 and 8 further provided with a second device in accordance with the first embodiment of the present invention;

FIG. 11 is a cross-sectional view of a first routing circuitry in accordance with the first embodiment of the present invention;

FIG. 12 is a cross-sectional view of the structure of FIG. 11 further provided with a heat spreader in accordance with the first embodiment of the present invention;

FIG. 13 is a cross-sectional view of the structure of FIG. 12 further provided with a second routing circuitry to finish the fabrication of a wiring board in accordance with the first embodiment of the present invention;

FIG. 14 is a cross-sectional view showing the step of stacking the structure of FIG. 9 on the wiring board of FIG. 13 in accordance with the first embodiment of the present invention;

FIG. 15 is a cross-sectional view of the structure of FIG. 9 electrically coupled to the wiring board of FIG. 13 to finish the fabrication of a semiconductor assembly in accordance with the first embodiment of the present invention;

FIG. 16 is a cross-sectional view of the structure of FIG. 15 further provided with a third device in accordance with the first embodiment of the present invention;

FIG. 17 is a cross-sectional view of another aspect of the semiconductor assembly in accordance with the first embodiment of the present invention;

FIG. 18 is a cross-sectional view of yet another aspect of the semiconductor assembly in accordance with the first embodiment of the present invention;

FIG. 19 is a cross-sectional view of the structure of FIG. 4 further provided with a molding compound in accordance with the second embodiment of the present invention;

FIG. 20 is a cross-sectional view of the structure of FIG. 19 further provided with via openings in accordance with the second embodiment of the present invention;

FIG. 21 is a cross-sectional view of the structure of FIG. 20 further provided with conductive vias and exterior conductive traces in accordance with the second embodiment of the present invention;

FIGS. 22 and 23 are cross-sectional and bottom perspective views, respectively, of the structure of FIG. 21 after removal of the sacrificial carrier in accordance with the second embodiment of the present invention;

FIG. 24 is a cross-sectional view of a wiring board in accordance with the second embodiment of the present invention;

FIG. 25 is a cross-sectional view of the structure of FIG. 24 further provided with a second device having first bumps thereon in accordance with the second embodiment of the present invention;

FIG. 26 is a cross-sectional view of the structure of FIG. 25 further provided with second bumps in accordance with the second embodiment of the present invention;

FIG. 27 is a cross-sectional view showing the step of stacking the structure of FIG. 22 on the structure of FIG. 26 in accordance with the second embodiment of the present invention;

FIG. 28 is a cross-sectional view of the structure of FIG. 22 electrically coupled to the structure of FIG. 26 to finish the fabrication of a semiconductor assembly in accordance with the second embodiment of the present invention;

FIG. 29 is a cross-sectional view of the structure of FIG. 28 further provided with a resin in accordance with the second embodiment of the present invention;

FIG. 30 is a cross-sectional view of another aspect of the semiconductor assembly in accordance with the second embodiment of the present invention;

FIGS. 31 and 32 are cross-sectional and bottom perspective views, respectively, of alignment guides formed on a heat spreader in accordance with the third embodiment of the present invention;

FIGS. 33 and 34 are cross-sectional and bottom perspective views, respectively, of the structure of FIGS. 31 and 32 further provided with first devices in accordance with the third embodiment of the present invention;

FIG. 35 is a cross-sectional view of the structure of FIG. 33 provided with a molding compound in accordance with the third embodiment of the present invention;

FIG. 36 is a cross-sectional view of the structure of FIG. 35 after removal of a bottom portion of the molding compound in accordance with the third embodiment of the present invention;

FIGS. 37 and 38 are cross-sectional and bottom perspective views, respectively, of the structure of FIG. 36 further provided with routing traces in accordance with the third embodiment of the present invention;

FIG. 39 is a cross-sectional view of the structure of FIG. 37 further provided with a dielectric layer and via openings in accordance with the third embodiment of the present invention;

FIGS. 40 and 41 are cross-sectional and bottom perspective views, respectively, of the structure of FIG. 39 further provided with conductive traces in accordance with the third embodiment of the present invention;

FIGS. 42 and 43 are cross-sectional and bottom perspective views, respectively, of the structure of FIGS. 40 and 41 further provided with second devices in accordance with the third embodiment of the present invention;

FIG. 44 is a cross-sectional view of the structure of FIG. 36 further provided with a dielectric layer and via openings in accordance with the third embodiment of the present invention;

FIG. 45 is a cross-sectional view of the structure of FIG. 44 further provided with conductive traces in accordance with the third embodiment of the present invention;

FIG. 46 is a cross-sectional view of the structure of FIG. 45 further provided with second devices in accordance with the third embodiment of the present invention;

FIG. 47 is a cross-sectional view of a diced state of the panel-scale structure of FIG. 46 in accordance with the third embodiment of the present invention;

FIG. 48 is a cross-sectional view of the structure corresponding to a diced unit in FIG. 47 in accordance with the third embodiment of the present invention;

FIGS. 49 and 50 are cross-sectional and top perspective views, respectively, of a wiring board in accordance with the third embodiment of the present invention;

FIG. 51 is a cross-sectional view showing the step of stacking the structure of FIG. 48 on the wiring board of FIG. 49 in accordance with the third embodiment of the present invention;

FIG. 52 is a cross-sectional view of the structure of FIG. 48 electrically coupled to the wiring board of FIG. 49 to finish the fabrication of a semiconductor assembly in accordance with the third embodiment of the present invention;

FIG. 53 is a cross-sectional view of the structure of FIG. 52 further provided with a third device in accordance with the third embodiment of the present invention;

FIG. 54 is a cross-sectional view of the structure with a first routing circuitry formed on a sacrificial carrier in accordance with the fourth embodiment of the present invention;

FIG. 55 is a cross-sectional view of the structure of FIG. 54 further provided with first devices in accordance with the fourth embodiment of the present invention;

FIG. 56 is a cross-sectional view of the structure of FIG. 55 further provided with a molding compound in accordance with the fourth embodiment of the present invention;

FIG. 57 is a cross-sectional view of the structure of FIG. 56 after removal of the sacrificial carrier in accordance with the fourth embodiment of the present invention;

FIG. 58 is a cross-sectional view of the structure of FIG. 57 further provided with a second device in accordance with the fourth embodiment of the present invention;

FIG. 59 is a cross-sectional view showing the step of stacking the structure of FIG. 58 on the wiring board of FIG. 49 in accordance with the fourth embodiment of the present invention;

FIG. 60 is a cross-sectional view of the structure of FIG. 58 electrically coupled to the wiring board of FIG. 49 to finish the fabrication of a semiconductor assembly in accordance with the fourth embodiment of the present invention;

FIG. 61 is a cross-sectional view of the structure of FIG. 60 further provided with a heat spreader in accordance with the fourth embodiment of the present invention;

FIG. 62 is a cross-sectional view of the structure of FIG. 60 further provided with another wiring board in accordance with the fourth embodiment of the present invention;

FIG. 63 is a cross-sectional view of the structure of FIG. 62 further provided with third devices in accordance with the fourth embodiment of the present invention; and

FIG. 64 is a cross-sectional view of another aspect of the semiconductor assembly in different configuration in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

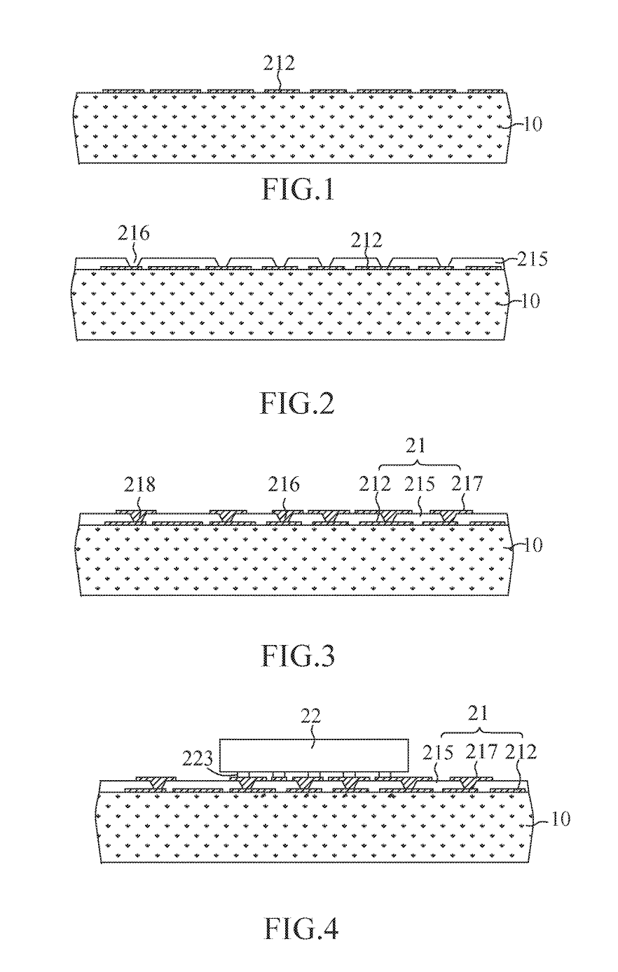

FIGS. 1-13 are schematic views showing a method of making a semiconductor assembly that includes a buildup circuitry 21, a first device 22, an array of vertical connecting elements 24, a molding compound material 25, a second device 31, a first routing circuitry 33, a heat spreader 34 and a second routing circuitry 35 in accordance with the first embodiment of the present invention.

FIG. 1 is a cross-sectional view of the structure with routing traces 212 formed on a sacrificial carrier 10. In this illustration, the sacrificial carrier 10 is a single-layer structure. The sacrificial carrier 10 typically is made of copper, aluminum, iron, nickel, tin, stainless steel, silicon, or other metals or alloys, but any other conductive or non-conductive material also may be used. In this embodiment, the sacrificial carrier 10 is made of an iron-based material. The routing traces 212 typically are made of copper and can be pattern deposited by numerous techniques, such as electroplating, electroless plating, evaporating, sputtering or their combinations, or be thin-film deposited followed by a metal patterning process. For a conductive sacrificial carrier 10, the routing traces 212 are deposited typically by plating of metal. The metal patterning techniques include wet etching, electro-chemical etching, laser-assist etching, and their combinations with an etch mask (not shown) thereon that defines the routing traces 212.

FIG. 2 is a cross-sectional view of the structure with a dielectric layer 215 on the sacrificial carrier 10 as well as the routing traces 212 and via openings 216 in the dielectric layer 215. The dielectric layer 215 is deposited typically by lamination or coating, and contacts and covers and extends laterally on the sacrificial carrier 10 and the routing traces 212 from above. The dielectric layer 215 typically has a thickness of 50 microns, and can be made of epoxy resin, glass-epoxy, polyimide, or the like. After the deposition of the dielectric layer 215, the via openings 216 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The via openings 216 extend through the dielectric layer 215 and are aligned with selected portions of the routing traces 212.

Referring now to FIG. 3, conductive traces 217 are formed on the dielectric layer 215 by metal deposition and metal patterning process. The conductive traces 217 extend from the routing traces 212 in the upward direction, fill up the via openings 216 to form metallized vias 218 in direct contact with the routing traces 212, and extend laterally on the dielectric layer 215. As a result, the conductive traces 217 can provide horizontal signal routing in both the X and Y directions and vertical routing through the via openings 216 and serve as electrical connections for the routing traces 212.

The conductive traces 217 can be deposited as a single layer or multiple layers by any of numerous techniques, such as electroplating, electroless plating, evaporating, sputtering, or their combinations. For instance, they can be deposited by first dipping the structure in an activator solution to render the dielectric layer 215 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the conductive traces 217 by any of numerous techniques such as wet etching, electro-chemical etching, laser-assist etching, or their combinations, with an etch mask (not shown) thereon that defines the conductive traces 217.

At this stage, the formation of a buildup circuitry 21 on the sacrificial carrier 10 is accomplished. In this illustration, the buildup circuitry 21 is a multi-layered buildup circuitry and includes routing traces 212, a dielectric layer 215 and conductive traces 217.

FIG. 4 is a cross-sectional view of the structure with a first device 22 electrically coupled to the buildup circuitry 21. The first device 22 can be electrically coupled to the conductive traces 217 of the buildup circuitry 21 using conductive bumps 223 in contact with the first device 22 and the buildup circuitry 21 by thermal compression, solder reflow or thermosonic bonding. In this example, the first device 22 is illustrated as a semiconductor chip.

FIG. 5 is a cross-sectional view of the structure with metal posts 241 on the buildup circuitry 21. The metal posts 241 are electrically connected to and contact the conductive traces 217 of the buildup circuitry 21 to serve as vertical connecting elements 24 around the first device 22.

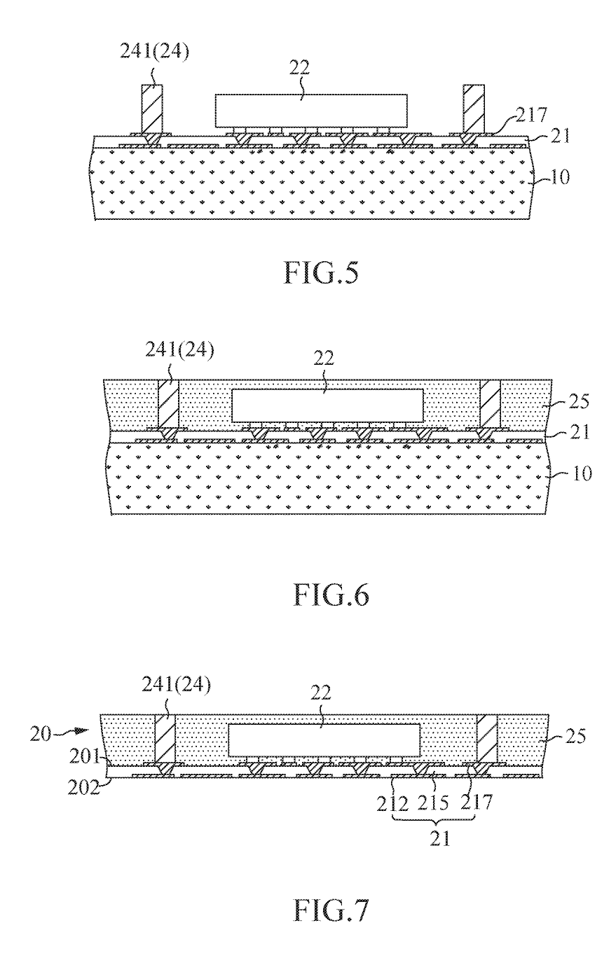

FIG. 6 is a cross-sectional view of the structure with a molding compound 25 on the buildup circuitry 21 and around the first device 22 and the vertical connecting elements 24 by, for example, resin-glass lamination, resin-glass coating or molding. The molding compound 25 covers the buildup circuitry 21 and the first device 22 from above and surrounds and conformally coats and covers sidewalls of the first device 22 and the vertical connecting elements 24.

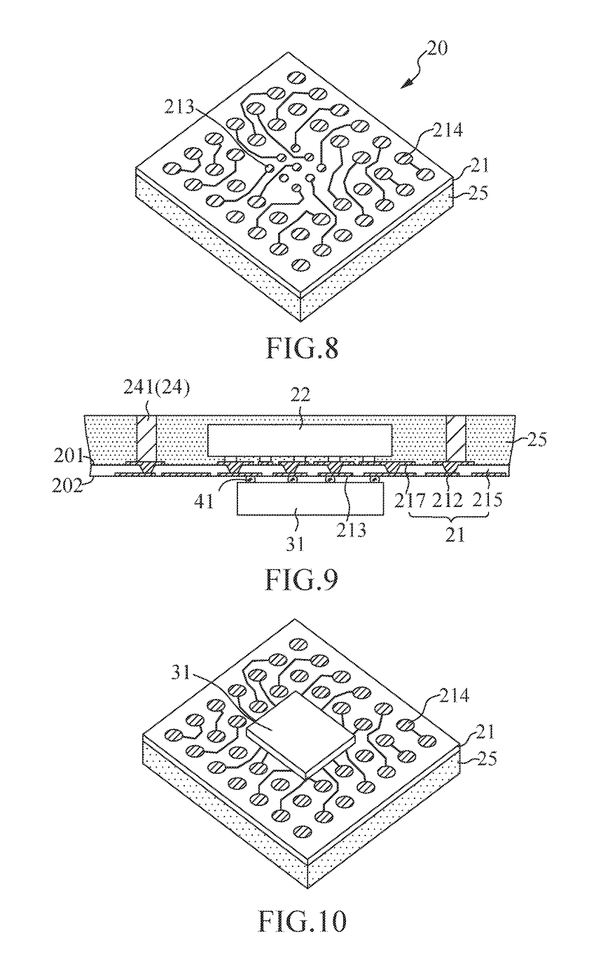

FIGS. 7 and 8 are cross-sectional and bottom perspective views, respectively, of the structure after removal of the sacrificial carrier 10. The sacrificial carrier 10 can be removed to expose the buildup circuitry 21 from below by numerous techniques, such as wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 10 made of an iron-based material is removed by a chemical etching solution that is selective between copper and iron so as to prevent the copper routing traces 212 from being etched during removal of the sacrificial carrier 10. Accordingly, the first surface 201 of the buildup circuitry 21 is electrically coupled to the first device 22 and the vertical connecting elements 24, and the second surface 202 of the buildup circuitry 21 is provided with electrical contacts for next connection from the downward direction. As shown in FIG. 8, the routing traces 212 include first contact pads 213 and second contact pads 214. The second contact pads 214 have larger pad size and pitch than those of the first contact pads 213. As a result, the first contact pads 213 can provide electrical contacts for another semiconductor chip, whereas the second contact pads 214 can provide electrical contacts for a next level interconnect structure.

At this stage, a first component 20 is accomplished and includes a buildup circuitry 21, a first device 22, an array of vertical connecting elements 24, and a molding compound 25.

FIGS. 9 and 10 are cross-sectional and bottom perspective views, respectively, of the structure with a second device 31 electrically coupled to the buildup circuitry 21. The second device 31 is flip-chip mounted to the second surface 202 of the buildup circuitry 21 by an array of first bumps 41 in contact with the first contact pads 213 of the buildup circuitry 21.

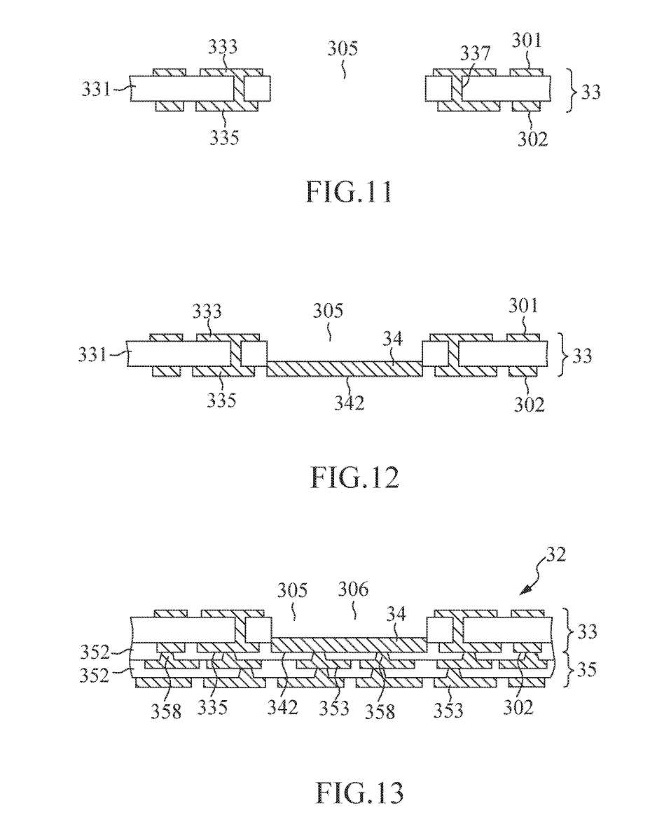

FIG. 11 is a cross-sectional view of a first routing circuitry 33. The first routing circuitry 33 has a through opening 305 extending from its first surface 301 to its second surface 302. In this illustration, the first routing circuitry 33 is an interconnect substrate that includes an insulating layer 331, a first wiring layer 333, a second wiring layer 335, and metallized through vias 337. The insulating layer 331 can be made of epoxy resin, glass-epoxy, polyimide, or the like. The first wiring layer 333 and the second wiring layer 335 are disposed on opposite sides of the insulating layer 331. The metallized through vias 337 extend through the insulating layer 331 and are electrically coupled to the first wiring layer 333 and the second wiring layer 335.

FIG. 12 is a cross-sectional view of the structure with a heat spreader 34 disposed in the through opening 305 of the first routing circuitry 33. The heat spreader 34 can be made of a thermally conductive material, such as metal, alloy, silicon, ceramic or graphite. In this embodiment, the heat spreader 34 is a metal layer and has a backside surface 342 substantially coplanar with the second surface 302 of the first routing circuitry 33 from below.

FIG. 13 is a cross-sectional view of the structure with a second routing circuitry 35 formed on the backside surface 342 and the second surface 302 of the first routing circuitry 33. In this illustration, the second routing circuitry 35 is a multi-layered buildup circuitry without a core layer, and includes multiple dielectric layers 352 and conductive traces 353 in an alternate fashion. The conductive traces 353 extend laterally on the dielectric layers 352 and include metallized vias 358 in the dielectric layers 352. Accordingly, the second routing circuitry 35 can be electrically coupled to the first routing circuitry 33 and the heat spreader 34 through the metallized vias 358 embedded in the dielectric layers 352 and in contact with the second wiring layer 335 and the heat spreader 34.

At this stage, a wiring board 32 is accomplished and includes a first routing circuitry 33, a heat spreader 34 and a second routing circuitry 35. As the depth of the through opening 305 is more than the thickness of the heat spreader 34, the exterior surface of the heat spreader 34 and the sidewall surface of the through opening 305 of the first routing circuitry 33 forms a cavity 306 in the through opening 305 of the first routing circuitry 33. As a result, the heat spreader 34 can provide thermal dissipation for a device accommodated in the cavity 306, whereas the combination of the first routing circuitry 33 and the second routing circuitry 35 offers electrical contacts for next connection from two opposite sides of the wiring board 32.

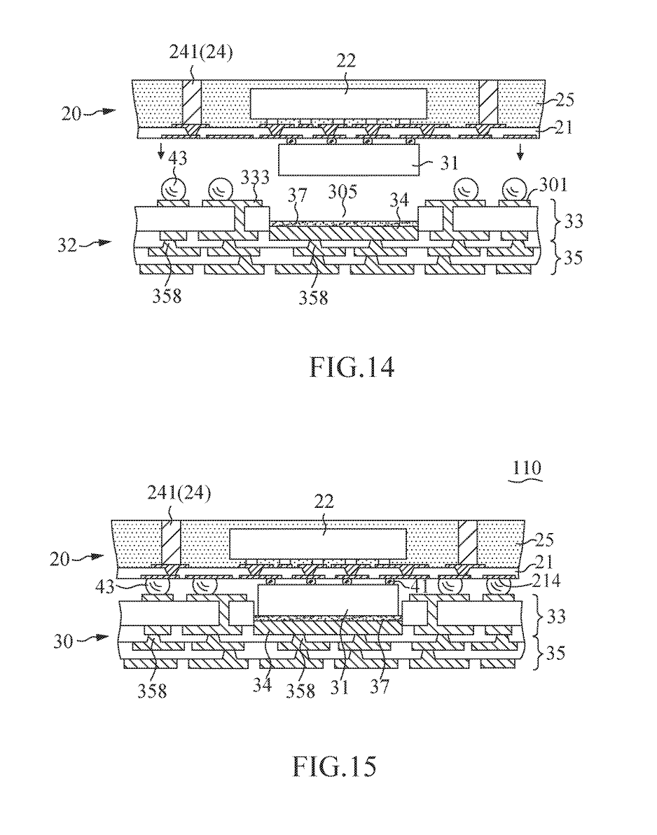

FIG. 14 is a cross-sectional view showing the step of stacking the structure of FIG. 9 over the wiring board 32 of FIG. 13. Before the stacking process, a thermally conductive material 37 is dispensed on the heat spreader 34, and an array of second bumps 43 are mounted on the first wiring layer 333 at the first surface 301 of the first routing circuitry 33. The thermally conductive material 37 can be a solder (e.g., AuSn) or a silver/epoxy adhesive.

FIG. 15 is a cross-sectional view of the structure with the second device 31 attached to the heat spreader 34 and the buildup circuitry 21 electrically coupled to the first routing circuitry 33. The second device 31 is inserted into the cavity 306 and thermally conductible to the heat spreader 34 by the thermally conductive material 37. The first routing circuitry 33 is electrically coupled to the buildup circuitry 21 by the second bumps 43 in contact with the second contact pads 214.

Accordingly, as shown in FIG. 15, a semiconductor assembly 110 is accomplished and includes a first component 20 and a second component 30. In this illustration, the first component 20 includes a buildup circuitry 21, a first device 22, an array of vertical connecting elements 24 and a molding compound 25, whereas the second component 30 includes a second device 31, a first routing circuitry 33, a heat spreader 34 and a second routing circuitry 35. The first component 20 is stacked over and face-to-face electrically coupled to the second component 30 by an array of first bumps 41 and an array of second bumps 43, and the heat spreader 34 is provided in the second component 30.

The first device 22 is embedded in the molding compound 25 and flip-chip electrically coupled to the buildup circuitry 21 from one side of the buildup circuitry 21. The vertical connecting elements 24 surround the first device 22 and are electrically coupled to the buildup circuitry 21 and laterally covered by the molding compound 25. The second device 31 is thermally conductible to the heat spreader 34 and spaced from and flip-chip electrically coupled to the buildup circuitry 21 by the first bumps 41 from the other side of the buildup circuitry 21. As such, the buildup circuitry 21 offers primary fan-out routing and the shortest interconnection distance between the first device 22 and the second device 31. The first routing circuitry 33 laterally surrounds peripheral edges of the second device 31 and the heat spreader 34, and is electrically coupled to and spaced from the buildup circuitry 21 by the second bumps 43. The second routing circuitry 35 covers the first routing circuitry 33 and the heat spreader 34 from below, and is electrically coupled to the first routing circuitry 33 and thermally conductible to the heat spreader 34 through metallized vias 358. As a result, the buildup circuitry 21, the first routing circuitry 33 and the second routing circuitry 35 can provide staged fan-out routing for the first device 22 and the second device 31.

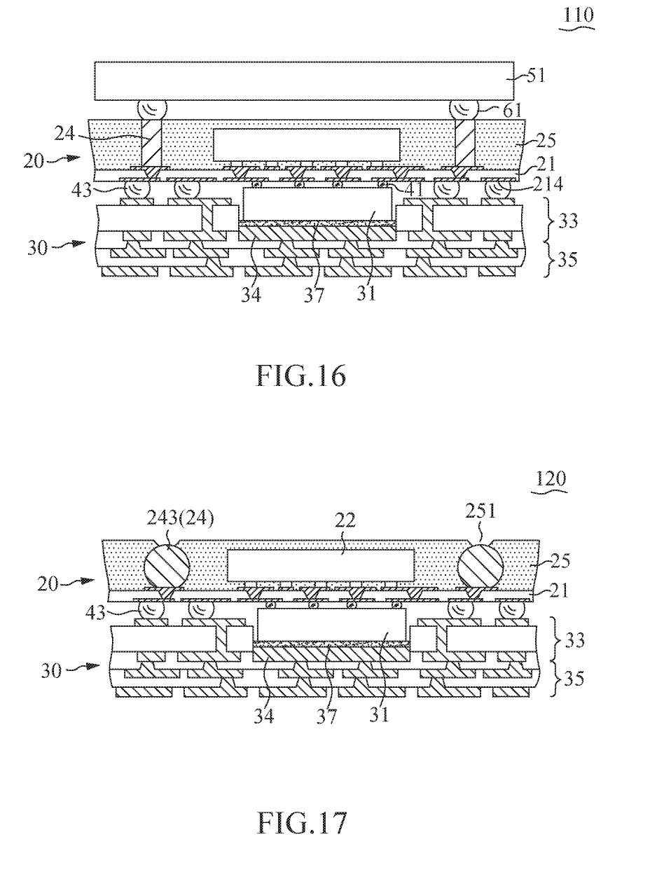

FIG. 16 is a cross-sectional view of the semiconductor assembly 110 of FIG. 15 further provided with a third device 51. The third device 51 is stacked over the first component 20, and electrically coupled to the vertical connecting elements 24 in the first component 20 through solder balls 61.

FIG. 17 is a cross-sectional view of another aspect of the semiconductor assembly according to the first embodiment of the present invention. The semiconductor assembly 120 is similar to that illustrated in FIG. 15, except that the first component 20 includes solder balls 243 as the vertical connecting elements 24. In this illustration, the molding compound 25 has a larger thickness than that of the solder balls 243, and has openings 251 to expose the solder balls 243 from above.

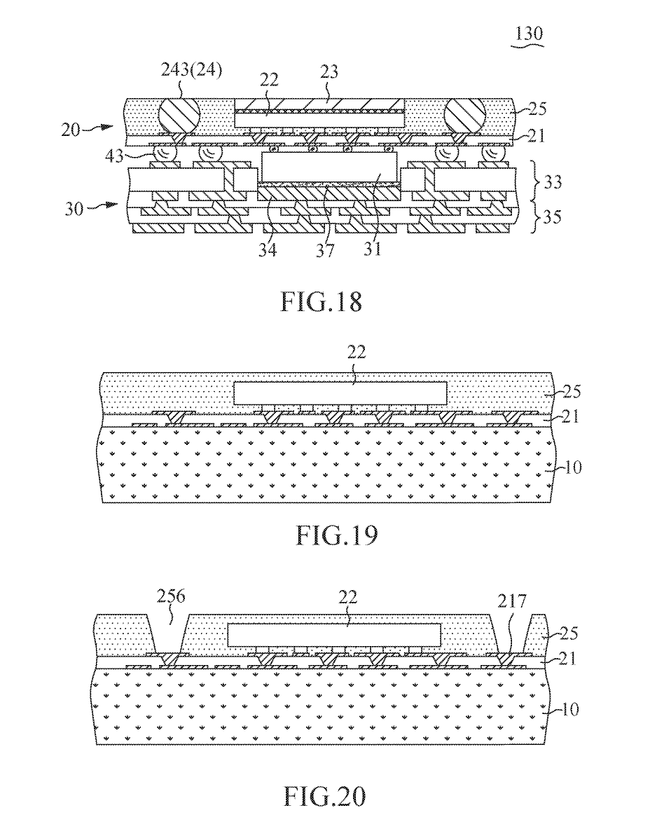

FIG. 18 is a cross-sectional view of yet another aspect of the semiconductor assembly according to the first embodiment of the present invention. The semiconductor assembly 130 is similar to that illustrated in FIG. 15, except that the first component 20 further includes a heat spreader 23, and the heat spreader 23 and the solder balls 243 have an exposed surface substantially coplanar with the exterior surface of the molding compound 25. In this aspect, the heat spreader 23 is attached to an inactive surface of the first device 22 before the provision of the molding compound 25 and is exposed from the exterior surface of the molding compound 25, whereas the solder balls 243 extend from the buildup circuitry 21 to the exterior surface of the molding compound 25 and serve as the vertical connecting elements 24 for next-level connection.

### Embodiment 2

FIGS. 19-29 are schematic views showing a method of making a semiconductor assembly with an external routing circuitry on the molding compound in accordance with the second embodiment of the present invention.

For purposes of brevity, any description in Embodiment 1 above is incorporated herein insofar as the same is applicable, and the same description need not be repeated.

FIG. 19 is a cross-sectional view of the structure with a molding compound 25 on the buildup circuitry 21 and the first device 22 of FIG. 4. The molding compound 25 covers the buildup circuitry 21 and the first device 22 from above and surrounds and conformally coats and covers sidewalls of the first device 22.

FIG. 20 is a cross-sectional view of the structure with via openings 256 in the molding compound 25. The via openings 256 are aligned with selected portions of the conductive traces 217 of the buildup circuitry 21 and extend through the molding compound 25.

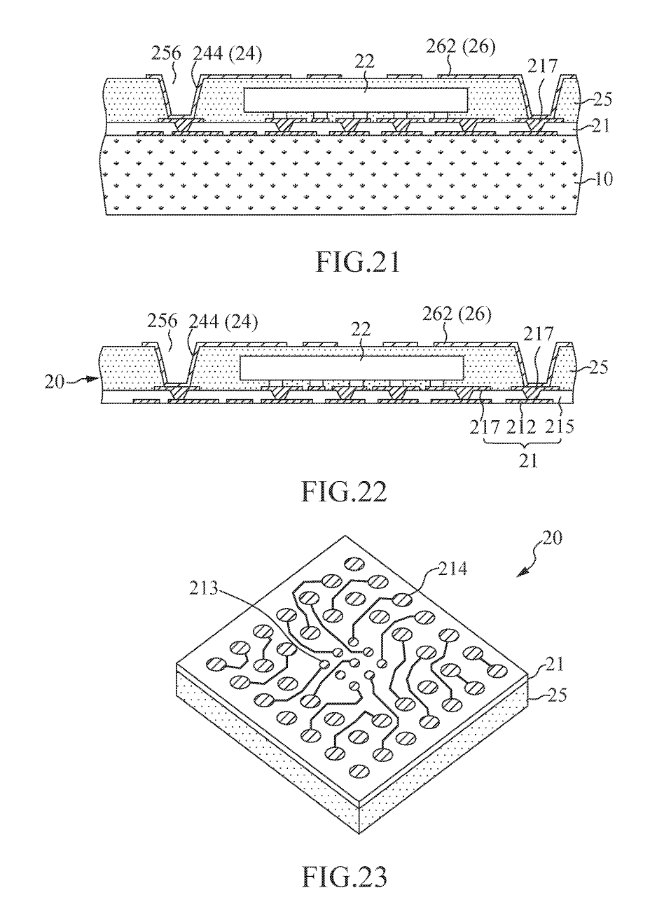

FIG. 21 is a cross-sectional view of the structure provided with conductive vias 244 in the via openings 256 and exterior conductive traces 262 on the molding compound 25. The conductive vias 244 are formed by metal deposition in the via openings 256 and contact the conductive traces 217 of the buildup circuitry 21 to serve as vertical connecting elements 24 surrounding the first device 22. The exterior conductive traces 262 are formed on the exterior surface of the molding compound 25 by metal deposition and metal patterning process and electrically coupled to the conductive vias 244.

At this stage, the formation of an external routing circuitry 26 on the exterior surface of the molding compound 25 is accomplished. In this illustration, the external routing circuitry 26 includes exterior conductive traces 262 that laterally extend on the exterior surface of the molding compound 25 and contact and are electrically coupled to the vertical connecting elements 24 in the molding compound 25.

FIGS. 22 and 23 are cross-sectional and bottom perspective views, respectively, of the structure with the buildup circuitry 21 exposed from below by removing the sacrificial carrier 10. As shown in FIG. 23, the routing traces 212 include first contact pads 213 and second contact pads 214. The second contact pads 214 have larger pad size and pitch than those of the first contact pads 213. At this stage, a first component 20 is accomplished and includes a buildup circuitry 21, a first device 22, an array of vertical connecting elements 24, a molding compound 25, and an external routing circuitry 26.

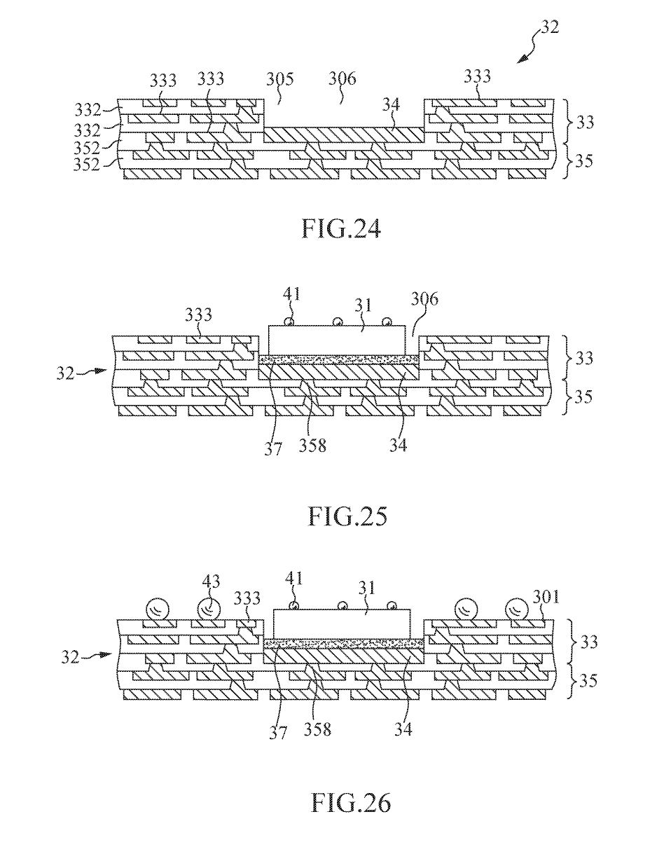

FIG. 24 is a cross-sectional view of a wiring board 32. The wiring board 32 is similar to that illustrated in FIG. 13, except that the first routing circuitry 33 is a multi-layered buildup circuitry without a core layer, and includes multiple dielectric layers 332 and conductive traces 333 in an alternate fashion.

FIG. 25 is a cross-sectional view of the structure with a second device 31 attached to the heat spreader 34. The second device 31 is provided with first bumps 41 on its active surface and thermally conductible to the heat spreader 34 by a thermally conductive material 37 in contact with its inactive surface. As a result, the heat spreader 34 can provide thermal dissipation for the second device 31 disposed within the cavity 306 of the wiring board 32.

FIG. 26 is a cross-sectional view of the structure with second bumps 43 mounted on the first routing circuitry 33. The second bumps 43 contact and are electrically coupled to the conductive traces 333 at the first surface 301 of the first routing circuitry 33.

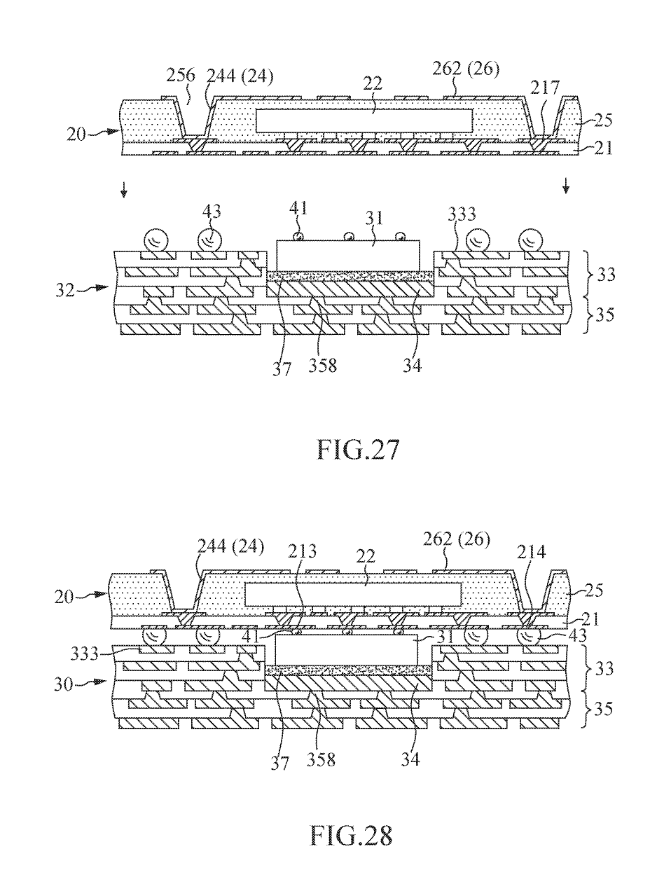

FIG. 27 is a cross-sectional view showing the step of stacking the first component 20 of FIG. 22 over the structure of FIG. 26. In this illustration, the first device 22 is placed face-down, whereas the second device 31 is placed face-up.

FIG. 28 is a cross-sectional view of the structure with the second device 31 and the first routing circuitry 33 electrically coupled to the buildup circuitry 21. The first bumps 41 contact and are electrically coupled to the first contact pads 213 of the buildup circuitry 21 to provide electrical connections between the buildup circuitry 21 and the second device 31. The second bumps 43 contact and are electrically coupled to the second contact pads 214 of the buildup circuitry 21 to provide electrical connections between the buildup circuitry 21 and the conductive traces 333 of the first routing circuitry 33.

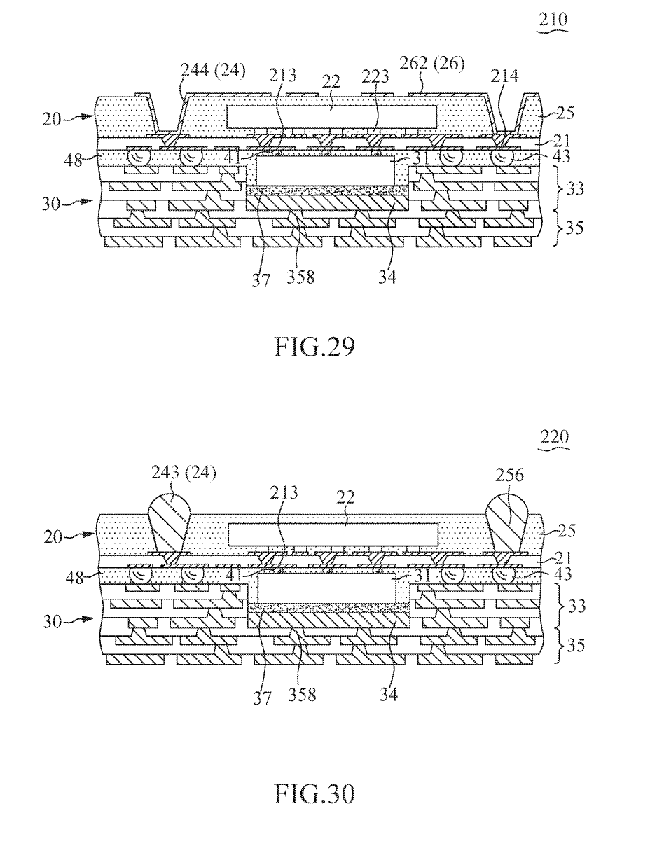

FIG. 29 is a cross-sectional view of the structure provided with a resin 48. Optionally, the resin 48 can be further provided to fill in the space between the buildup circuitry 21 and the first routing circuitry 33 and between the buildup circuitry 21 and the second device 31, and fill up the gap located in the cavity 306 between the second device 31 and sidewalls of the cavity 306.

Accordingly, as shown in FIG. 29, a semiconductor assembly 210 is accomplished and includes a first component 20 and a second component 30. The first component 20 is stacked over and face-to-face electrically coupled to the second component 30 by an array of first bumps 41 and an array of second bumps 43. In this illustration, the first component 20 includes a buildup circuitry 21, a first device 22, an array of vertical connecting elements 24, a molding compound 25 and an exterior routing circuitry 26, whereas the second component 30 includes a second device 31, a first routing circuitry 33, a heat spreader 34 and a second routing circuitry 35.

The first device 22 and the second device 31 are disposed at two opposite sides of the buildup circuitry 21 and face-to-face electrically connected to each other through the buildup circuitry 21 therebetween. The first device 22 is embedded in the molding compound 25 and surrounded by the vertical connecting elements 24 and electrically coupled to the buildup circuitry 21 by conductive bumps 223. The second device 31 is laterally surrounded by the first routing circuitry 33 and thermally conductible to the heat spreader 34 and electrically coupled to and spaced from the buildup circuitry 21 by first bumps 41. The first routing circuitry 33 is electrically coupled to the buildup circuitry 21 through second bumps 43, whereas the external routing circuitry 26 is electrically coupled to the buildup circuitry 21 through the vertical connecting elements 24 in the molding compound 25. The second routing circuitry 35 is electrically coupled to the first routing circuitry 33 and the heat spreader 34 by the metallized vias 358. As a result, the buildup circuitry 21, the external routing circuitry 26, the first routing circuitry 33 and the second routing circuitry 35 are electrically connected to each other, and provide staged fan-out routing for the first device 22 and the second device 31.

FIG. 30 is a cross-sectional view of another aspect of the semiconductor assembly according to the second embodiment of the present invention. The semiconductor assembly 220 is similar to that illustrated in FIG. 29, except that the first component 20 includes no external routing circuitry 26 on the molding compound 25 and the vertical connecting elements 24 are formed in different configuration. In this aspect, the first component 20 is accomplished by deposition of the solder balls 243 into the via openings 256 in the molding compound 25 of FIG. 20 and then removal of the sacrificial carrier 10. As a result, the solder balls 243 contact the buildup circuitry 21 and fill up the via openings 256 of the molding compound 25 to serve as vertical connecting elements 24.

### Embodiment 3

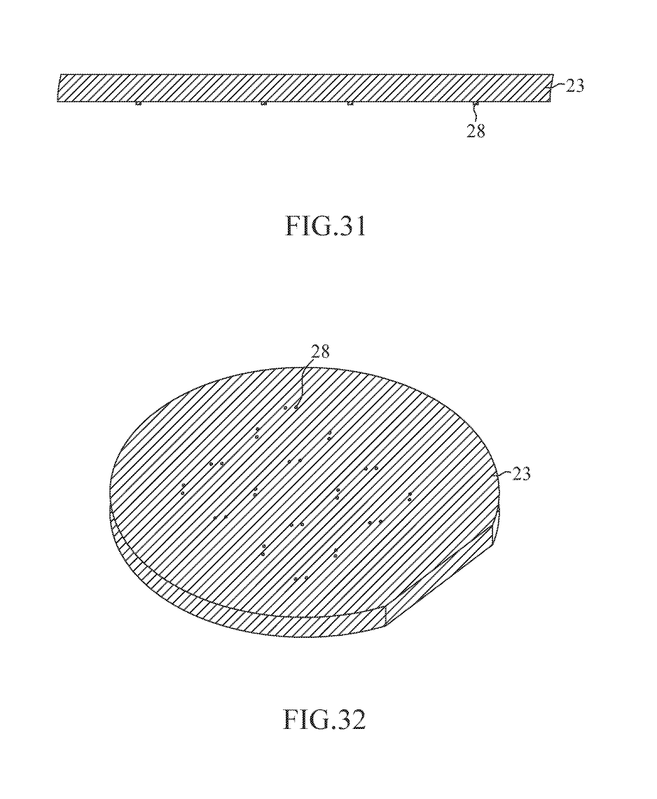

FIGS. 31-52 are schematic views showing a method of making a semiconductor assembly with the first and second routing circuitries laterally extending beyond peripheral edges of the first component in accordance with the third embodiment of the present invention.

For purposes of brevity, any description in Embodiments above is incorporated herein insofar as the same is applicable, and the same description need not be repeated.

FIGS. 31 and 32 are cross-sectional and bottom perspective views, respectively, of the structure with multiple sets of alignment guides 28 on a heat spreader 23. The thickness of the heat spreader 23 preferably ranges from 0.1 to 1.0 mm. The alignment guides 28 project from a surface of the heat spreader 23 and can have a thickness of 5 to 200 microns. In this embodiment, the heat spreader 23 has a thickness of 0.5 mm, whereas the alignment guides 28 have a thickness of 50 microns. The alignment guides 28 can be pattern deposited by numerous techniques, such as electroplating, electroless plating, evaporating, sputtering or their combinations using photolithographic process, or be thin-film deposited followed by a metal patterning process. The metal patterning techniques include wet etching, electro-chemical etching, laser-assist etching, and their combinations with an etch mask (not shown) thereon that defines the alignment guides 28. For an electrically conductive heat spreader 23, the alignment guides 28 are deposited typically by plating of metal (such as copper). Alternatively, if an electrically non-conductive heat spreader 23 is used, a solder mask or photo resist may be used to form the alignment guides 28. As shown in FIG. 32, each set of the alignment guides 28 consists of plural posts and conforms to four corners of a subsequently disposed device. However, the alignment guide patterns are not limited thereto and can be in other various patterns against undesirable movement of the subsequently disposed device. For instance, the alignment guides 28 may consist of a continuous or discontinuous strip and conform to four sides, two diagonal corners or four corners of a subsequently disposed device. Alternatively, the alignment guides 28 may laterally extend to the peripheral edges of the heat spreader 23 and have inner peripheral edges that conform to the peripheral edges of a subsequently disposed device.

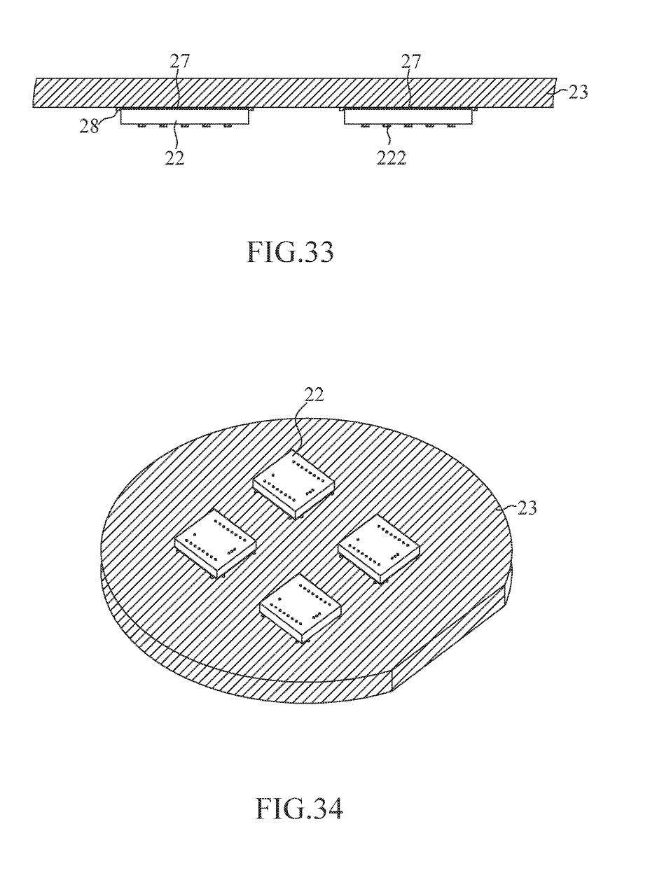

FIGS. 33 and 34 are cross-sectional and bottom perspective views, respectively, of the structure with first devices 22 attached to the heat spreader 23 typically by a thermally conductive material 27. In this illustration, the first device 22 each includes protruded bumps 222 at its active surface, and is attached to the heat spreader 23 with its inactive surface facing the heat spreader 23. Each set of the alignment guides 28 is laterally aligned with and in close proximity to the peripheral edges of each first device 22. The device placement accuracy is provided by the alignment guides 28 that extend beyond the inactive surface of the first devices 22 in the downward direction and are located beyond and laterally aligned with the four corners of the first devices 22 in the lateral directions. Because the alignment guides 28 are in close proximity to and conform to the four corners of the first devices 22 in lateral directions, any undesirable movement of the first devices 22 due to adhesive curing can be avoided. Preferably, a gap in between the alignment guides 28 and the first devices 22 is in a range of about 5 to 50 microns. Additionally, the first devices 22 also may be attached without the alignment guides 28.

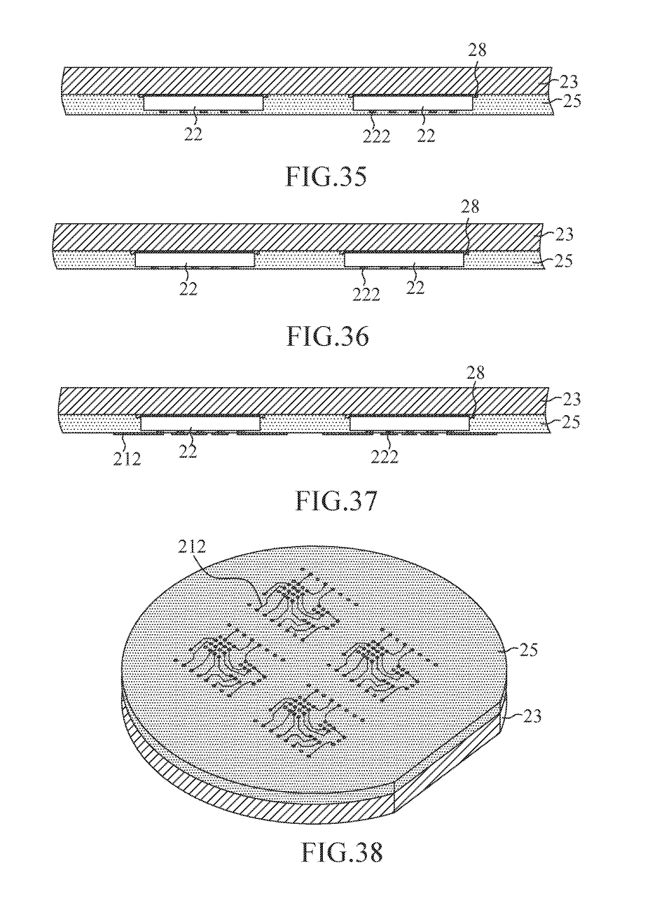

FIG. 35 is a cross-sectional view of the structure provided with a molding compound 25 on the first devices 22 and the heat spreader 23. The molding compound 25 covers the first devices 22 and the heat spreader 23 from below and surrounds and conformally coats and covers sidewalls of the first devices 22 and extends laterally from the first devices 22 to the peripheral edges of the structure.

FIG. 36 is a cross-sectional view of the structure with the protruded bumps 222 of the first devices 22 exposed from below. The bottom portion of the molding compound 25 can be removed by lapping, grinding or laser. After partial removal of the molding compound 25, the molding compound 25 has a bottom surface substantially coplanar with the exterior surface of the protruded bumps 222.

FIGS. 37 and 38 are cross-sectional and bottom perspective views, respectively, of the structure provided with routing traces 212 by metal deposition and metal patterning process. The routing traces 212 extend laterally on the molding compound 25 and are electrically coupled to the protruded bumps 222 of the first devices 22.

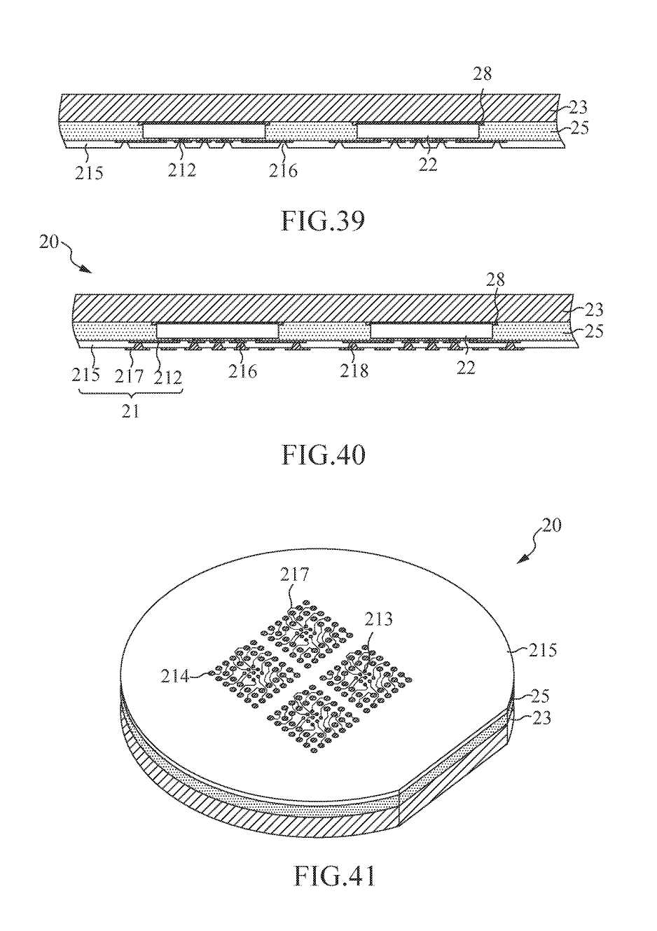

FIG. 39 is a cross-sectional view of the structure with a dielectric layer 215 on the molding compound 25 as well as the routing traces 212 and via openings 216 in the dielectric layer 215. The dielectric layer 215 contacts and covers and extends laterally on the molding compound 25 and the routing traces 212 from below. After the deposition of the dielectric layer 215, the via openings 216 are formed and extend through the dielectric layer 215 and are aligned with selected portions of the routing traces 212.

FIGS. 40 and 41 are cross-sectional and bottom perspective views, respectively, of the structure provided with conductive traces 217 on the dielectric layer 215 by metal deposition and metal patterning process. The conductive traces 217 extend from the routing traces 212 in the downward direction, fill up the via openings 216 to form metallized vias 218 in direct contact with the routing traces 212, and extend laterally on the dielectric layer 215. As shown in FIG. 41, the conductive traces 217 include first contact pads 213 and second contact pads 214. The second contact pads 214 have larger pad size and pitch than those of the first contact pads 213. As a result, the first contact pads 213 can provide electrical contacts for another device, whereas the second contact pads 214 can provide electrical contacts for a next level interconnect structure.

At this stage, a first component 20 is accomplished and includes a heat spreader 23, alignment guides 28, first devices 22, a molding compound 25, and a buildup circuitry 21. In this illustration, the buildup circuitry 21 includes routing traces 212, a dielectric layer 215 and conductive traces 217.

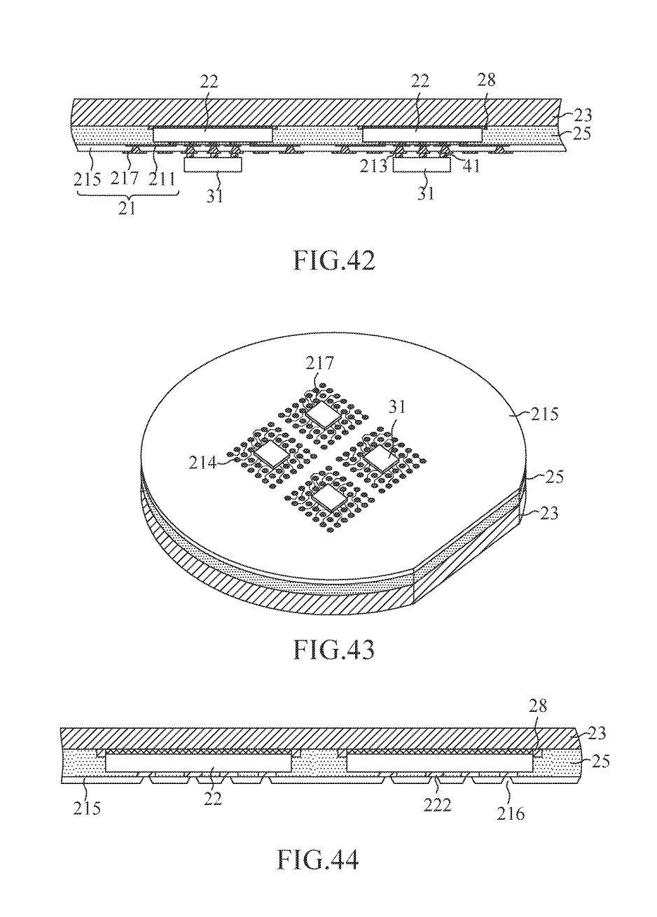

FIGS. 42 and 43 are cross-sectional and bottom perspective views, respectively, of the structure provided with second devices 31 electrically coupled to the buildup circuitry 21. The second devices 31 have an active surface facing the buildup circuitry 21, and can be electrically coupled to the first contact pads 213 of the conductive traces 217 using first bumps 41.

FIGS. 44-48 are cross-sectional views showing an alternative process of forming the structure having the second device 31 electrically coupled to a diced unit of first component 20.

FIG. 44 is a cross-sectional view of the structure with a dielectric layer 215 laminated/coated on the first devices 22 and the molding compound 25 and via openings 216 in the dielectric layer 215. The dielectric layer 215 contacts and covers and extends laterally on the protruded bumps 222 of the first devices 22 and the molding compound 25 from below. The via openings 216 extend through the dielectric layer 215 and are aligned with the protruded bumps 222 of the first devices 22.

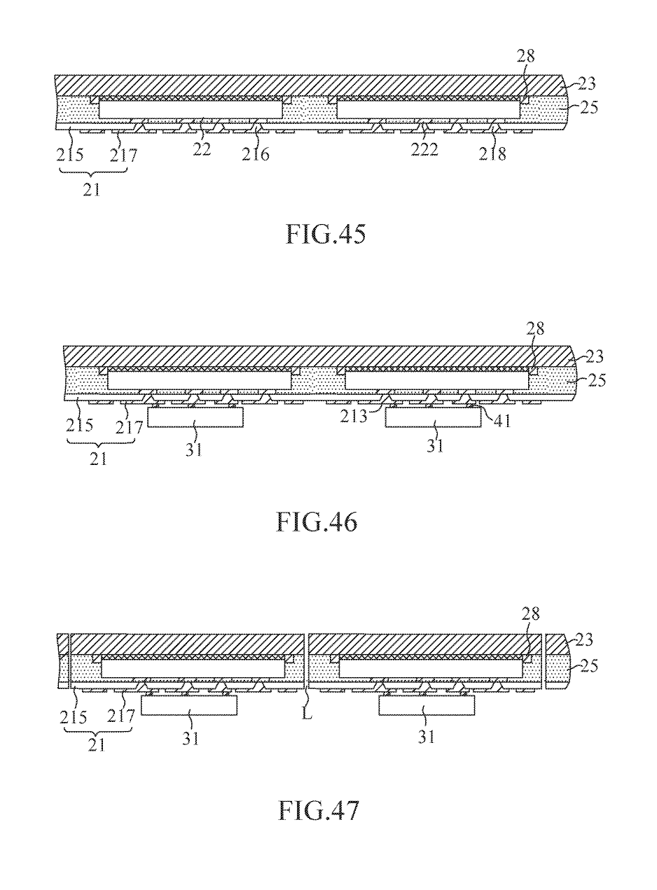

FIG. 45 is a cross-sectional view of the structure provided with conductive traces 217 on the dielectric layer 215 by metal deposition and metal patterning process. The conductive traces 217 extend from the protruded bumps 222 of the first devices 22 in the downward direction, fill up the via openings 216 to form metallized vias 218 in direct contact with the protruded bumps 222, and extend laterally on the dielectric layer 215.

FIG. 46 is a cross-sectional view of structure provided with second devices 31 on the conductive traces 217. The second devices 31 are electrically coupled to the first contact pads 213 of the conductive traces 217 using the first bumps 41.

FIG. 47 is a cross-sectional view of the panel-scale structure of FIG. 46 diced into individual pieces. In this illustration, the panel-scale structure is singulated into individual pieces along dicing lines “L”.

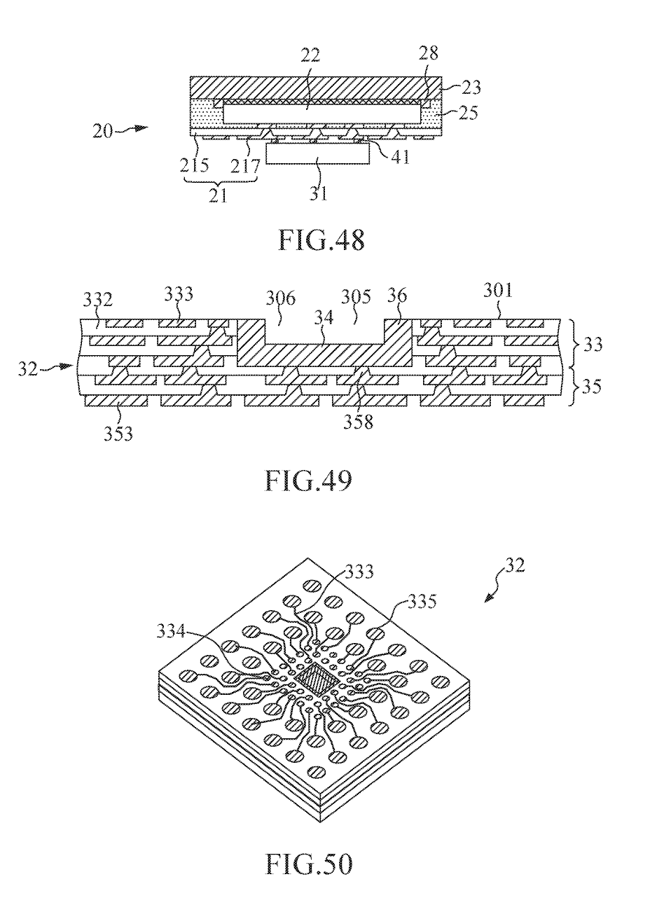

FIG. 48 is a cross-sectional view of an individual piece having a second device 31 electrically coupled to a first component 20 that includes a heat spreader 23, an alignment guide 28, a first device 22, a molding compound 25, and a buildup circuitry 21. In this illustration, the buildup circuitry 21 includes a dielectric 215 and conductive traces 217 laterally extending beyond peripheral edges of the first device 22 and the second device 31. The first device 22 is electrically coupled to the buildup circuitry 21 from above and enclosed by the heat spreader 23 and the molding compound 25, whereas the second device 31 is electrically coupled to the buildup circuitry 21 from below and is face-to-face electrically connected to the first device 22 through the buildup circuitry 21.

FIGS. 49 and 50 are cross-sectional and top perspective views, respectively, of a wiring board 32. The wiring board 32 is similar to that illustrated in FIG. 24, except that (i) it further includes a metal layer 36 that covers sidewalls of the through opening 305 of the first routing circuitry 33 and contacts the heat spreader 34, and (ii) the outmost conductive traces 333 of the first routing circuitry 33 at the first surface 301 includes first terminal pads 334 and second terminal pads 335. In this illustration, the metal layer 36 is integrally formed with the heat spreader 34, and the exterior surface of the heat spreader 34 and the lateral surface of the metal layer 36 forms a cavity 306 in the through opening 305 of the first routing circuitry 33. The pad size and the pad pitch of the first terminal pads 334 are larger than those of the first device 22 and the second device 31 and match the second contact pads 214 of the buildup circuitry 21. The pad size and the pad pitch of the second terminal pads 335 are larger than those of the first terminal pads 334 and match a next level interconnect structure.

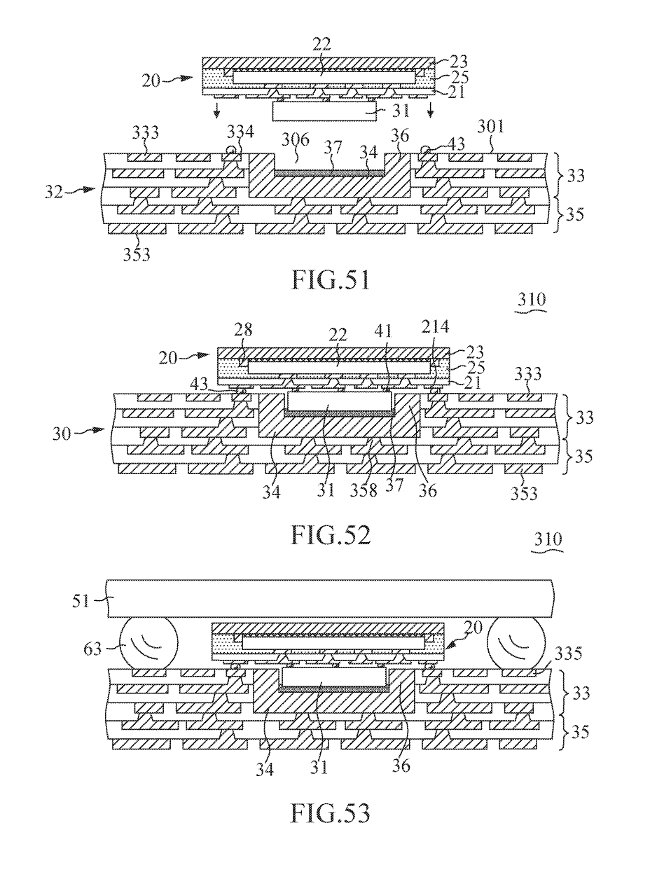

FIG. 51 is a cross-sectional view showing the step of stacking the structure of FIG. 48 over the wiring board 32 of FIG. 49. Before the stacking process, a thermally conductive material 37 is dispensed on the heat spreader 34, and second bumps 43 are mounted on the first terminal pads 334 of the first routing circuitry 33.

FIG. 52 is a cross-sectional view of the structure with the second device 31 attached to the heat spreader 34 and the buildup circuitry 21 electrically coupled to the first routing circuitry 33. The second device 31 is inserted into the cavity 306 and thermally conductible to the heat spreader 34 by the thermally conductive material 37. The first terminal pads 334 of the first routing circuitry 33 are electrically coupled to the second contact pads 214 of the buildup circuitry 21 by the second bumps 43.

Accordingly, as shown in FIG. 52, a semiconductor assembly 310 is accomplished and includes a first component 20 and a second component 30. In this illustration, the first component 20 includes a buildup circuitry 21, a first device 22, a heat spreader 23, a molding compound 25 and an alignment guide 28, whereas the second component 30 includes a second device 31, a first routing circuitry 33, a heat spreader 34, a second routing circuitry 35 and a metal layer 36.

The first device 22 is attached to the heat spreader 23 with the alignment guide 28 around its inactive surface and conforming to its four corners. The buildup circuitry 21 is electrically coupled to the first device 22 and laterally extends beyond peripheral edge of the first device 22 and on the molding compound 25 that laterally surrounds the first device 22. The second device 31 is face-to-face electrically connected to the first device 22 through the buildup circuitry 21 and first bumps 41 in contact with the buildup circuitry 21. As such, the buildup circuitry 21 offers the shortest interconnection distance between the first device 22 and the second device 31, and provides first level fan-out routing for the first device 22 and the second device 31. The heat spreader 34 covers the inactive surface of the second device 31 and is thermally conductible to the second device 31, whereas the metal layer 36 surrounds the sidewalls of the second device 31 and contacts the heat spreader 34. The metal layer 36 may also be integrally formed with the heat spreader 34. The first routing circuitry 33 includes conductive traces 333 laterally extending beyond peripheral edges of the buildup circuitry 21, and is electrically coupled to the buildup circuitry 21 through second bumps 43. The second routing circuitry 35 covers the first routing circuitry 33 and the heat spreader 34 from below, and is electrically coupled to the first routing circuitry 33 for signal routing and to the heat spreader 34 for ground connection through metallized vias 358. Accordingly, the combination of the first routing circuitry 33 and the second routing circuitry 35 can provide second level fan-out routing for the buildup circuitry 21 and electrical contacts for external connection, whereas the combination of the heat spreader 34 and the metal layer 36, electrically connected to the second routing circuitry 35, provides thermal dissipation and EMI shielding for the second device 31.

FIG. 53 is a cross-sectional view of the semiconductor assembly 310 of FIG. 52 further provided with a third device 51. The third device 51 is stacked over the first component 20, and electrically coupled to the second terminal pads 335 of the first routing circuitry 33 through solder balls 63.

### Embodiment 4

FIGS. 54-60 are schematic views showing a method of making another semiconductor assembly with the first and second routing circuitries laterally extending beyond peripheral edges of the first component and no alignment guide around the first device in accordance with the fourth embodiment of the present invention.

For purposes of brevity, any description in Embodiments above is incorporated herein insofar as the same is applicable, and the same description need not be repeated.

FIG. 54 is a cross-sectional view of the structure with a buildup circuitry 21 detachably adhered over a sacrificial carrier 10. In this illustration, the sacrificial carrier 10 is a double-layer structure and includes a support sheet 111 and a barrier layer 113 deposited on the support sheet 111. The buildup circuitry 21 is formed on the barrier layer 113 by the steps illustrated in FIGS. 1-3. The barrier layer 113 can have a thickness of 0.001 to 0.1 mm and may be a metal layer that is inactive against chemical etching during chemical removal of the support sheet 111 and can be removed without affecting the routing traces 212. For instance, the barrier layer 113 may be made of tin or nickel when the support sheet 111 and the routing traces 212 are made of copper. Further, in addition to metal materials, the barrier layer 113 can also be a dielectric layer such as a peelable laminate film. In this embodiment, the support sheet 111 is a copper sheet, and the barrier layer 113 is a nickel layer of 5 microns in thickness.

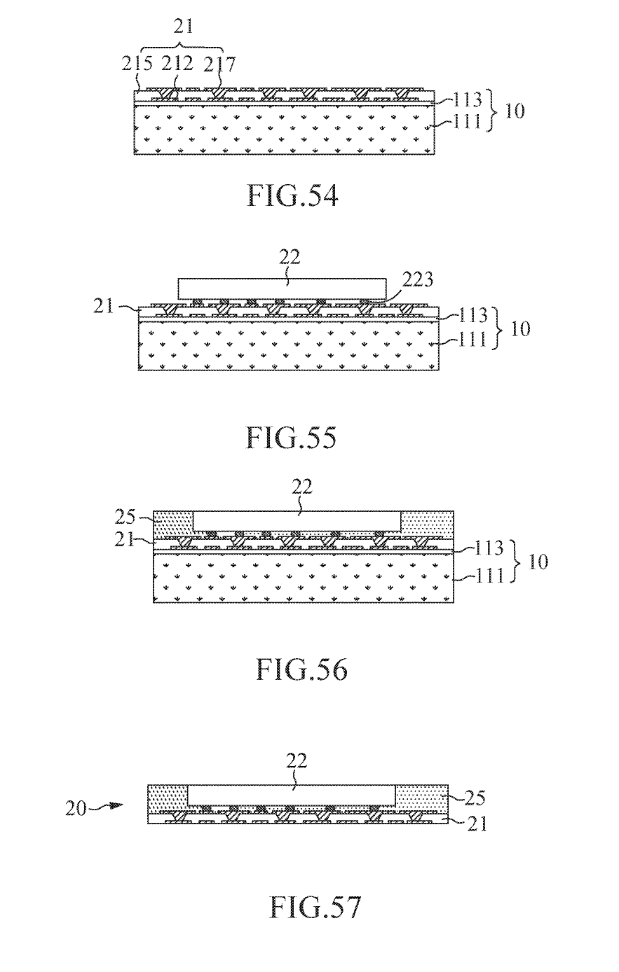

FIG. 55 is a cross-sectional view of the structure with first device 22 electrically coupled to the buildup circuitry 21 from above. The first device 22 is electrically coupled to the buildup circuitry 21 using conductive bumps 223.

FIG. 56 is a cross-sectional view of the structure with a molding compound 25 on the buildup circuitry 21 and around the first device 22. The molding compound 25 covers the buildup circuitry 21 from above and surrounds and conformally coats and covers sidewalls of the first device 22. As an alternative, the step of providing the molding compound 25 may be omitted.

FIG. 57 is a cross-sectional view of the structure after removal of the sacrificial carrier 10. The buildup circuitry 21 is exposed from below by removing the support sheet 111 made of copper using an alkaline etching solution and then removing the barrier layer 113 made of nickel using an acidic etching solution. In another aspect, if the barrier layer 113 is a peelable laminate film, the barrier layer 113 can be removed by mechanical peeling or plasma ashing.

At this stage, a first component 20 is accomplished and includes a buildup circuitry 21, a first device 22 and a molding compound 25.

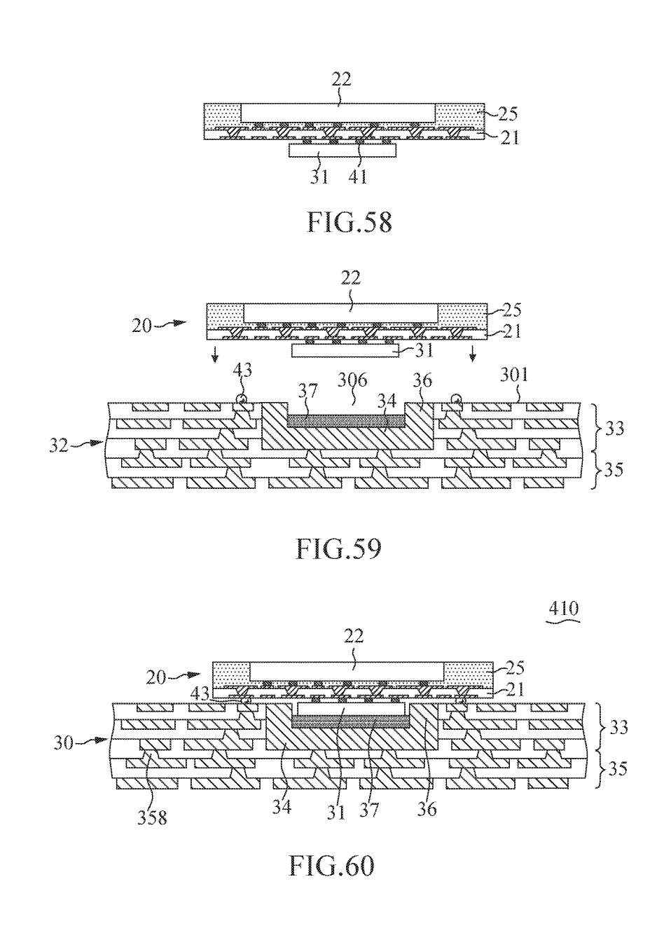

FIG. 58 is a cross-sectional view of the structure with a second device 31 electrically coupled to the buildup circuitry 21. The second device 31 is flip-chip mounted to the buildup circuitry 21 by an array of first bumps 41 in contact with the buildup circuitry 21.

FIG. 59 is a cross-sectional view showing the step of stacking the structure of FIG. 58 over the wiring board 32 of FIG. 49. Before the stacking process, a thermally conductive material 37 is dispensed on the heat spreader 34, and second bumps 43 are mounted on the first routing circuitry 33.

FIG. 60 is a cross-sectional view of the structure with the second device 31 attached to the heat spreader 34 and the buildup circuitry 21 electrically coupled to the first routing circuitry 33 to finish the fabrication of a semiconductor assembly 410. The second device 31 is accommodated in the cavity 306 and thermally conductible to the heat spreader 34 by the thermally conductive material 37. The first routing circuitry 33 is electrically coupled to the buildup circuitry 21 by the second bumps 43.

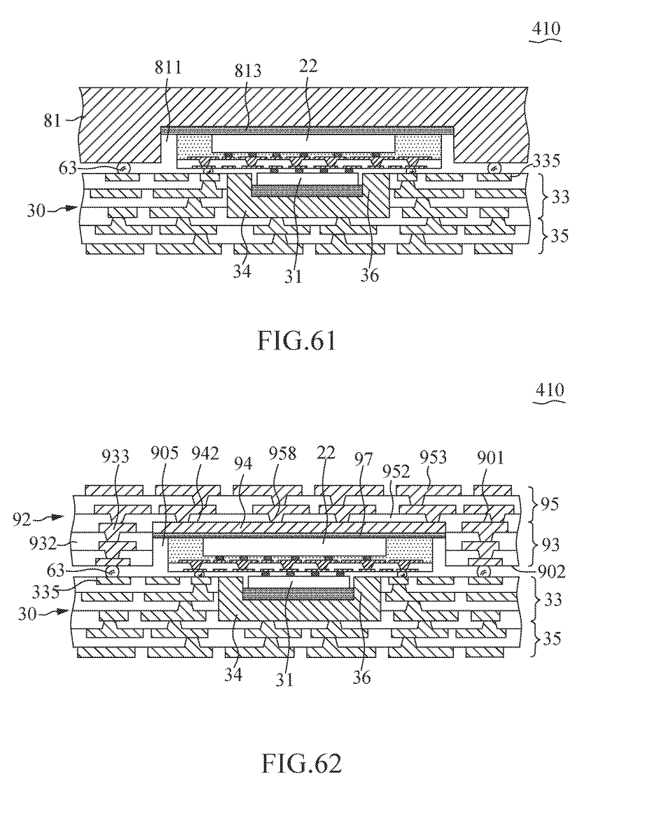

FIG. 61 is a cross-sectional view of the semiconductor assembly 410 of FIG. 60 further provided with a heat spreader 81 having a cavity 811. The first component 20 is inserted into the cavity 811 of the heat spreader 81 and thermally conductible to the heat spreader 81 by a thermally conductive material 813 in contact with the first device 22 and the heat spreader 81. Further, the heat spreader 81 is electrically coupled to the second terminal pads 335 of the first routing circuitry 33 for ground connection by solder balls 63.

FIG. 62 is a cross-sectional view of the semiconductor assembly 410 of FIG. 60 further provided with an additional wiring boards 92. The wiring board 92 is stacked over the first component 20, and includes a third routing circuitry 93, a heat spreader 94 and a fourth routing circuitry 95. In this illustration, both the third routing circuitry 93 and the fourth routing circuitry 95 are multi-layered buildup circuitries without a core layer, and each includes multiple dielectric layers 932, 952 and conductive traces 933, 953 in an alternate fashion to provide electrical contacts at two opposite sides of the wiring board 92. The third routing circuitry 93 has a through opening 905 extending from its first surface 901 to its second surface 902, and is electrically coupled to the second terminal pads 335 of the first routing circuitry 33 by solder balls 63. The heat spreader 94 is disposed in the through opening 905 of the third routing circuitry 93, and has a backside surface 942 substantially coplanar with the first surface 901 of the third routing circuitry 93. The first component 20 is attached to and thermally conductible to the heat spreader 94 by a thermally conductive material 97 and laterally surrounded by the third routing circuitry 93. The fourth routing circuitry 95 is disposed on the first surface 901 of the third routing circuitry 93 and the backside surface 942 of the heat spreader 94, and includes metallized vias 958 embedded in the dielectric layer 952 and in contact with the conductive traces 933 of the third routing circuitry 93 and the heat spreader 94.

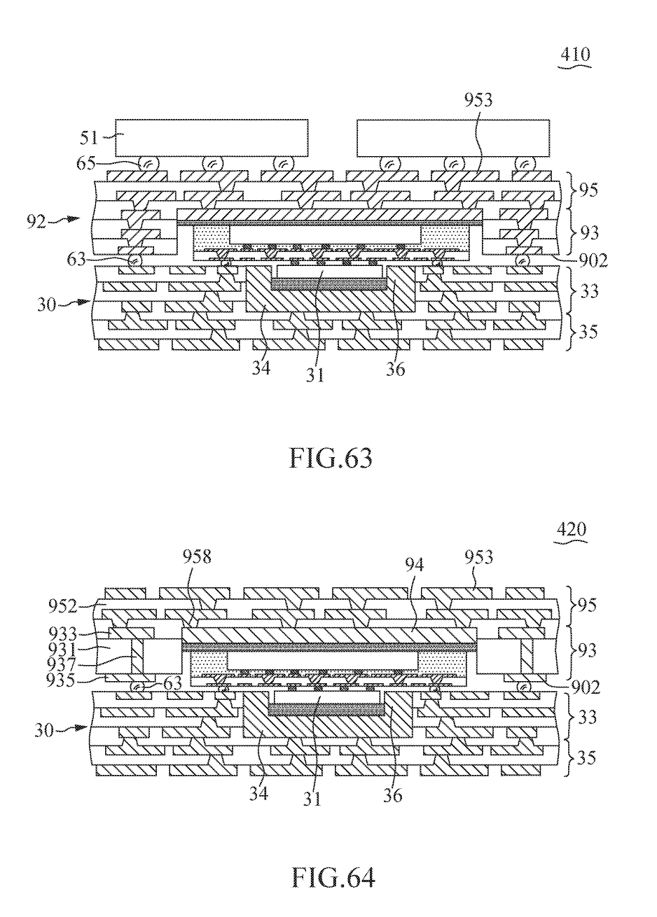

FIG. 63 is a cross-sectional view of the semiconductor assembly 410 of FIG. 62 further provided with third devices 51. The third devices 51 are stacked over and electrically coupled to the conductive traces 953 of the fourth routing circuitry 95 through solder balls 65.

FIG. 64 is a cross-sectional view of another aspect of the semiconductor assembly according to the fourth embodiment of the present invention. The semiconductor assembly 420 is similar to that illustrated in FIG. 62, except that the third routing circuitry 93 is an interconnect substrate that includes an insulating layer 931, a first wiring layer 933, a second wiring layer 935, and metallized through vias 937. The first wiring layer 933 and the second wiring layer 935 are disposed on opposite sides of the insulating layer 931. The metallized through vias 937 extend through the insulating layer 931 and are electrically coupled to the first wiring layer 933 and the second wiring layer 935. The fourth routing circuitry 95 includes metallized vias 958 in contact with the first wiring layer 933 of the third routing circuitry 93 and the heat spreader 94.

The semiconductor assemblies described above are merely exemplary. Numerous other embodiments are contemplated. In addition, the embodiments described above can be mixed-and-matched with one another and with other embodiments depending on design and reliability considerations. The first component can include multiple first devices and be electrically coupled to multiple second devices, and the second device can share or not share the through opening of the first routing circuitry with other second devices. For instance, a through opening can accommodate a single second device, and the first routing circuitry can include multiple through openings arranged in an array for multiple second devices. Alternatively, numerous second devices can be positioned within a single through opening of the first routing circuitry. Additionally, a first component can share or not share the wiring board with other first components. For instance, a single first component can be connected to the wiring board. Alternatively, numerous first components may be connected to the wiring board. For instance, four first components in a 2×2 array can be connected to the wiring board, and the first and second routing circuitries of the wiring board can include additional conductive traces to receive and route additional first components.

As illustrated in the aforementioned embodiments, a distinctive semiconductor assembly is configured, and includes a first component and a second component in a face-to-face stacking configuration. The first component includes a first device, a buildup circuitry and optionally a molding compound, and the second component includes a second device, a first routing circuitry, a second routing circuitry and a heat spreader. In a preferred embodiment, the first device is sealed in the molding compound, whereas the second device is placed within a through opening of the first routing circuitry and attached to the heat spreader and not sealed by a molding compound. Further, for external connection, an array of vertical connecting elements may be provided in the molding compound of the first component, or the first routing circuitry may laterally extend beyond peripheral edges of the first component to provide electrical contacts at its first surface for next connection. Optionally, a resin may be further provided to fill in a space between the buildup circuitry and the second device and between the buildup circuitry and the first routing circuitry and fill up a gap located in the through opening of the first routing circuitry between the second device and the sidewalls of the through opening.

For the convenience of below description, the direction in which the first surfaces of the buildup circuitry and the first routing circuitry face is defined as the first direction, and the direction in which the second surfaces of the buildup circuitry and the first routing circuitry face is defined as the second direction.

The first and second devices can be semiconductor chips, packaged devices, or passive components. In a preferred embodiment, a first component having the first device electrically coupled to the buildup circuitry is prepared by the steps of: electrically coupling the first device to the buildup circuitry detachably adhered over a sacrificial carrier; optionally providing the molding compound and the vertical connecting elements over the buildup circuitry; and removing the sacrificial carrier from the buildup circuitry. The first device can be electrically coupled to the buildup circuitry by a well-known flip chip bonding process with its active surface facing in the buildup circuitry using bumps without metallized vias in contact with the first device. Likewise, after removal of the sacrificial carrier, the second device can be electrically coupled to the buildup circuitry by a well-known flip chip bonding process with its active surface facing in the buildup circuitry using bumps without metallized vias in contact with the second device. Additionally, the first component may be fabricated by another process that includes steps of: attaching the first device to a heat spreader typically by a thermally conductive material; providing the molding compound over the heat spreader; and forming the buildup circuitry over an active surface of the first device and the molding compound, with the first device being electrically coupled to the buildup circuitry. In this process, the buildup circuitry can be electrically coupled to the first device by direct build-up process. Further, an alignment guide may be provided to ensure the placement accuracy of the first device on the heat spreader. Specifically, the alignment guide projects from a surface of the heat spreader, and the first device is attached to the heat spreader with the alignment guide laterally aligned with the peripheral edges of the first device. As the alignment guide extending beyond the inactive surface of the first device in the second direction and in close proximity to the peripheral edges of the first device, any undesirable movement of the first device can be avoided. As a result, a higher manufacturing yield for the buildup circuitry interconnected to the first device can be ensured.

The alignment guide can have various patterns against undesirable movement of the first device. For instance, the alignment guide can include a continuous or discontinuous strip or an array of posts. Alternatively, the alignment guide may laterally extend to the peripheral edges of the heat spreader and have inner peripheral edges that conform to the peripheral edges of the first device. Specifically, the alignment guide can be laterally aligned with four lateral surfaces of the first device to define an area with the same or similar topography as the first device and prevent the lateral displacement of the first device. For instance, the alignment guide can be aligned along and conform to four sides, two diagonal corners or four corners of the first device so as to confine the dislocation of the first device laterally. Besides, the alignment guide around the inactive surface of the first device preferably has a height in a range of 5-200 microns.

The buildup circuitry can be a multi-layered buildup circuitry and include at least one dielectric layer and conductive traces that fill up via openings in the dielectric layer and extend laterally on the dielectric layer. The dielectric layer and the conductive traces are serially formed in an alternate fashion and can be in repetition when needed. The buildup circuitry has one surface facing in the first direction and provided with electrical contacts for first device connection, and the other surface facing in the second direction and provided with first and second contact pads respectively for second device connection and first routing circuitry connection. The first contact pads have pad size and pitch that match I/O pads of the second device, and can be electrically coupled to the second device by first bumps. The second contact pads have pad size and pad pitch that are larger than those of the first contact pads and I/O pads of the first and second devices and match the first routing circuitry, and can be interconnected to the first routing circuitry by second bumps. As a result, the buildup circuitry can provide primary fan-out routing/interconnection and the shortest interconnection distance between the first and second devices.

The first routing circuitry includes electrical contacts at its first surface for the buildup circuitry connection from the first direction, whereas the second routing circuitry includes electrical contacts at its exterior surface for next-level connection from the second direction. The first routing circuitry has a through opening extending from its first surface to its second surface to accommodate the heat spreader and the second device therein. Preferably, the first routing circuitry is a multi-layered routing circuitry and laterally surround peripheral edges of the second device and the heat spreader. For instance, the first routing circuitry may be an interconnect substrate that includes an insulating layer, wiring layers respectively on both opposite sides of the insulating layer, and metallized through vias formed through the insulating layer to provide electrical connection between both the wiring layers. Alternatively, the first routing circuitry may be a multi-layered buildup circuitry without a core layer, and includes dielectric layers and conductive traces in repetition and alternate fashion. Accordingly, the outmost conductive traces at both the first and second surfaces of the first routing circuitry can provide electrical contacts for the buildup circuitry connection from its first surface and for the second routing circuitry connection from its second surface. The second routing circuitry is provided to cover the backside surface of the heat spreader and the second surface of the first routing circuitry, and is electrically coupled to the heat spreader and the first routing circuitry by metallized vias embedded in a dielectric layer of the second routing circuitry and in contact with the backside surface of the heat spreader and the second surface of the first routing circuitry. Accordingly, the heat spreader, covered by the dielectric layer of the second routing circuitry from the second direction, can be mechanically supported by the second routing circuitry and provide thermal dissipation and EMI shielding for the second device attached thereto using a thermally conductive material. Preferably, the second routing circuitry is a multi-layered routing circuitry and laterally extends to peripheral edges of the first routing circuitry. For instance, the second routing circuitry may be a multi-layered buildup circuitry without a core layer, and includes dielectric layers and conductive traces in repetition and alternate fashion. The conductive traces include metallized vias in the dielectric layer and extend laterally on the dielectric layer. Additionally, the heat spreader preferably is a metal layer, and an additional metal layer may be further provided to contact and completely cover a remaining portion of sidewalls of the through opening of the first routing circuitry.

For next-level connection, an array of vertical connecting elements may be provided in the molding compound of the first component. The vertical connecting elements can include metal posts, solder balls or conductive vias, and provide electrical contacts for next-level connection. As a result, a third device can be stacked over the first component and electrically coupled to the vertical connecting elements. Alternatively, no vertical connecting elements are provided in the first component, and the first routing circuitry includes at least one conductive trace that laterally extends beyond the peripheral edges of the buildup circuitry to provide electrical contacts for external connection. More specifically, the first routing circuitry may include first and second terminal pads at its first surface respectively for the buildup circuitry connection and external connection from the first direction. Preferably, the first terminal pads have pad size and pad pitch that are larger than I/O pads of the first and second devices and match second contact pads of the buildup circuitry, whereas the second terminal pads have pad size and pad pitch that are larger than those of the first terminal pads and match next-level connection. Accordingly, in the aspect of the first routing circuitry laterally extending beyond the first component, a third device or an additional heat spreader may be further stacked over the first component and electrically coupled to the second terminal pads of the first routing circuitry by, for example, solder balls, from the first surface of the first routing circuitry. When the additional heat spreader is mounted over the first surface of the first routing circuitry, the first component can be disposed in a cavity of the additional heat spreader, and the first device of the first component is thermally conductible to the additional heat spreader through a thermally conductive material. Alternatively, an additional wiring board may be stacked over the first component and electrically coupled to the second terminal pads of the first routing circuitry from the first surface of the first routing circuitry. More specifically, the additional wiring board can include a third routing circuitry, a fourth routing circuitry and an additional heat spreader. The third routing circuitry has a through opening extending from its first surface to its second surface to accommodate the additional heat spreader and the first component therein. Preferably, the third routing circuitry is a multi-layered routing circuitry and laterally surround peripheral edges of the first component and the additional heat spreader. For instance, the third routing circuitry may be an interconnect substrate that includes an insulating layer, wiring layers respectively on both opposite sides of the insulating layer, and metallized through vias formed through the insulating layer to provide electrical connection between both the wiring layers. Alternatively, the third routing circuitry may be a multi-layered buildup circuitry without a core layer, and includes dielectric layers and conductive traces in repetition and alternate fashion. In any case, the third routing circuitry can include electrical contacts at its opposite first and second surfaces for electrical connection with the first routing circuitry and with the fourth routing circuitry. Accordingly, the third routing circuitry can be electrically coupled to the first routing circuitry by, for example, solder balls, between the first surface of the first routing circuitry and the second surface of the third routing circuitry, whereas the fourth routing circuitry can be electrically coupled to the first surface of the third routing circuitry by metallized vias. Further, the fourth routing circuitry is also electrically coupled to the heat spreader disposed in the through opening of the third routing circuitry by metallized vias for ground connection. As a result, when the first component is disposed in the through opening of the third routing circuitry, the heat spreader of the additional wiring board can provide thermal dissipation and EMI shielding for the first device attached thereto using a thermally conductive material. Preferably, the fourth routing circuitry is a multi-layered routing circuitry and laterally extends to peripheral edges of the third routing circuitry. For instance, the fourth routing circuitry may be a multi-layered buildup circuitry without a core layer, and include dielectric layers and conductive trace in repetition and alternate fashion. As a result, the fourth routing circuitry can include conductive traces at its exterior surface to provide electrical contacts from the first direction, and a third device may be optionally stacked over and electrically coupled to the exterior surface of the fourth routing circuitry.

Optionally, an external routing circuitry may be further formed over the exterior surface of the molding compound in the aspect of the vertical connecting elements being provided in the first component. The external routing circuitry may be a buildup circuitry and is electrically coupled to the vertical connecting elements. More specifically, the first component can further include conductive traces that contact and are electrically connected to the vertical connecting elements in the molding compound and laterally extend over the exterior surface of the molding compound. Further, the external routing circuitry may be a multi-layer routing circuitry that include one or more dielectric layers, via openings in the dielectric layer, and additional conductive traces if needed for further signal routing. The outmost conductive traces of the external routing circuitry can accommodate conductive joints, such as solder balls, for electrical communication and mechanical attachment with for the next level assembly or another electronic device.

The term “cover” refers to incomplete or complete coverage in a vertical and/or lateral direction. For instance, in the cavity-up position, the second routing circuitry covers the second device in the downward direction regardless of whether other elements such as the heat spreader and the thermally conductive material are between the second device and the second routing circuitry.

The phrases “attached to”, “attached on”, “mounted to” and “mounted on” includes contact and non-contact with a single or multiple element(s). For instance, the second device is attached to the heat spreader regardless of whether it is separated from the heat spreader by a thermally conductive material.

The phrase “aligned with” refers to relative position between elements regardless of whether elements are spaced from or adjacent to one another or one element is inserted into and extends into the other element. For instance, the alignment guide is laterally aligned with the first device since an imaginary horizontal line intersects the alignment guide and the first device, regardless of whether another element is between the alignment guide and the first device and is intersected by the line, and regardless of whether another imaginary horizontal line intersects the first device but not the alignment guide or intersects the alignment guide but not the first device. In a preferred embodiment, the metallized vias of the second routing circuitry contact and are aligned with the backside surface of the heat spreader and the second surface of the first routing circuitry.

The phrase “in close proximity to” refers to a gap between elements not being wider than the maximum acceptable limit. As known in the art, when the gap between the first device and the alignment guide is not narrow enough, the location error of the first device due to the lateral displacement of the first device within the gap may exceed the maximum acceptable error limit. In some cases, once the location error of the first device goes beyond the maximum limit, it is impossible to align the predetermined portion of the first device with a laser beam, resulting in the electrical connection failure between the first device and the buildup circuitry. According to the pad size of the first device, those skilled in the art can ascertain the maximum acceptable limit for a gap between the first device and the alignment guide through trial and error to ensure the metallized vias of the buildup circuitry being aligned with the I/O pads of the first device. Thereby, the description “the alignment guide is in close proximity to the peripheral edges of the first device” means that the gap between the peripheral edges of the first device and the alignment guide is narrow enough to prevent the location error of the first device from exceeding the maximum acceptable error limit. For instance, the gaps in between the first device and the alignment guide may be in a range of about 5 to 50 microns.

The phrases “electrical connection”, “electrically connected” and “electrically coupled” refer to direct and indirect electrical connection. For instance, in the aspect of the vertical connecting elements being provided in the molding compound, the vertical connecting elements directly contact and are electrically connected to the buildup circuitry, and the second device is spaced from and electrically connected to the buildup circuitry by the first bumps.

The “first direction” and “second direction” do not depend on the orientation of the semiconductor assembly, as will be readily apparent to those skilled in the art. For instance, the first surfaces of the buildup circuitry and the first routing circuitry face the first direction and the second surfaces of the buildup circuitry and the first routing circuitry face the second direction regardless of whether the semiconductor assembly is inverted. Thus, the first and second directions are opposite one another and orthogonal to the lateral directions. Furthermore, the first direction is the upward direction and the second direction is the downward direction in the cavity-up position, and the first direction is the downward direction and the second direction is the upward direction in the cavity-down position.

The semiconductor assembly according to the present invention has numerous advantages. For instance, the first and second devices are mounted on opposite sides of the buildup circuitry, which can offer the shortest interconnect distance between the first and second semiconductor devices. The buildup circuitry provides primary fan-out routing/interconnection for the first and second devices, whereas the vertical connecting elements offer electrical contacts for external connection or next-level routing circuitry connection. As the second device and the first routing circuitry are electrically coupled to the buildup circuitry by bumps, not by direct build-up process, the simplified process steps result in lower manufacturing cost. The external routing circuitry can provide external pads populated all over the area to increase external electrical contacts for next-level assembly. The heat spreader can provide thermal dissipation, electromagnetic shielding and moisture barrier for the second device. The second routing circuitry can provide mechanical support for the heat spreader and dissipate heat from the heat spreader. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A thermally enhanced semiconductor assembly with three dimensional integration, comprising:
a first component that includes a first device and a buildup circuitry, wherein the first device is electrically coupled to a first surface of the buildup circuitry;
a second component that includes a second device, a first routing circuitry, a second routing circuitry and a heat spreader, wherein (i) the first routing circuitry has a first surface, an opposite second surface, and a through opening extending from the first surface to the second surface, (ii) the heat spreader is disposed in the through opening and has a backside surface substantially coplanar with the second surface of the first routing circuitry, (iii) the second routing circuitry is disposed on the backside surface of the heat spreader and the second surface of the first routing circuitry and electrically connected to the first routing circuitry and thermally conductible to the heat spreader through metallized vias, and (iv) the second device is attached to the heat spreader with a thermally conductive material and laterally surrounded by the first routing circuitry; and
the first component is stacked over the second component, with the second device electrically coupled to a second surface of the buildup circuitry opposite to the first surface by an array of first bumps, and with the second surface of the buildup circuitry electrically coupled to the first surface of the first routing circuitry by an array of second bumps.

2. The semiconductor assembly of claim 1, further comprising a metal layer that is integrally formed with the heat spreader and disposed on sidewalls of the through opening

3. The semiconductor assembly of claim 1, wherein the first routing circuitry includes at least one conductive trace laterally extending beyond peripheral edges of the first component.

4. The semiconductor assembly of claim 3, further comprising a third device stacked over the first component and electrically coupled to the first surface of the first routing circuitry.

5. The semiconductor assembly of claim 3, further comprising a wiring board stacked over the first component, the wiring board including a third routing circuitry, a fourth routing circuitry and an additional heat spreader, wherein (i) the third routing circuitry has a first surface, an opposite second surface, and a through opening extending from the first surface to the second surface, (ii) the additional heat spreader is disposed in the through opening and has a backside surface substantially coplanar with the first surface of the third routing circuitry, (iii) the fourth routing circuitry is disposed on the backside surface of the additional heat spreader and the first surface of the third routing circuitry and electrically connected to the third routing circuitry and thermally conductible to the additional heat spreader through metallized vias, and (iv) the first component is attached to the additional heat spreader and laterally surrounded by the third routing circuitry.

6. The semiconductor assembly of claim 5, further comprising a third device stacked over and electrically coupled to the fourth routing circuitry.

7. The semiconductor assembly of claim 3, further comprising another heat spreader electrically coupled to the first surface of the first routing circuitry and thermally conductible to the first device of the first component.

8. The semiconductor assembly of claim 1, wherein the first component further includes a molding compound that surrounds the first device and covers the first surface of the buildup circuitry.

9. The semiconductor assembly of claim 8, wherein the first component further includes an array of vertical connecting elements in the molding compound that are electrically coupled to the buildup circuitry and extend towards an exterior surface of the molding compound.

10. The semiconductor assembly of claim 9, further comprising a third device stacked over the first component and electrically coupled to the vertical connecting elements of the first component.

11. The semiconductor assembly of claim 9, wherein the first component further includes an external routing circuitry disposed on the exterior surface of the molding compound and electrically coupled to the vertical connecting elements in the molding compound.

12. A method of making a thermally enhanced semiconductor assembly with three dimensional integration, comprising:
providing a first component that includes a first device and a buildup circuitry, wherein the first device is electrically coupled to a first surface of the buildup circuitry;
providing a wiring board that includes a first routing circuitry, a second routing circuitry and a heat spreader, wherein (i) the first routing circuitry has a first surface, an opposite second surface, and a through opening extending from the first surface to the second surface, (ii) the heat spreader is disposed in the through opening and has a backside surface substantially coplanar with the second surface of the first routing circuitry, and (iii) the second routing circuitry is disposed on the backside surface of the heat spreader and the second surface of the first routing circuitry and electrically connected to the first routing circuitry and thermally conductible to the heat spreader through metallized vias;
electrically coupling a second device to a second surface of the buildup circuitry of the first component opposite to the first surface through an array of first bumps; and
stacking the first component over the wiring board and electrically coupling the first surface of the first routing circuitry to the second surface of the buildup circuitry of the first component by an array of second bumps, with the second device attached to the heat spreader and laterally surrounded by the first routing circuitry.

13. The method of claim 12, further comprising a step of stacking a third device over the first component, wherein the third device is electrically coupled to the first surface of the first routing circuitry.

14. The method of claim 12, further comprising steps of:
providing an additional wiring board that includes a third routing circuitry, a fourth routing circuitry and an additional heat spreader, wherein (i) the third routing circuitry has a first surface, an opposite second surface, and a through opening extending from the first surface and the second surface, (ii) the additional heat spreader is disposed in the through opening and has a backside surface substantially coplanar with the first surface of the third routing circuitry, and (iii) the fourth routing circuitry is disposed on the backside surface of the additional heat spreader and the first surface of the third routing circuitry and electrically connected to the third routing circuitry and thermally conductible to the additional heat spreader through metallized vias; and
stacking the additional wiring board over the first component, with the second surface of the third routing circuitry electrically coupled to the first surface of the first routing circuitry, and with the first component attached to the additional heat spreader and laterally surrounded by the third routing circuitry.

15. The method of claim 14, further comprising a step of stacking a third device over the fourth routing circuitry, wherein the third device is electrically coupled to the fourth routing circuitry.

16. The method of claim 12, further comprising a step of stacking an additional heat spreader over the first component, wherein the additional heat spreader is electrically coupled to the first surface of the first routing circuitry and attached to the first device of the first component.

17. The method of claim 12, wherein the first component further includes a molding compound that surrounds the first device and covers the first surface of the buildup circuitry.

18. The method of claim 17, wherein the first component further includes an array of vertical connecting elements in the molding compound that are electrically coupled to the buildup circuitry.

19. The method of claim 18, further comprising a step of stacking a third device over the first component, wherein the third device is electrically coupled to the vertical connecting elements of the first component.

20. The method of claim 18, wherein the first component further includes an external routing circuitry disposed on the exterior surface of the molding compound and electrically coupled to the vertical connecting elements in the molding compound.
